(19) United States
(12) Patent Application Publication
(10) Pub. No.: US 2026/0371870 A1
(43) Pub. Date: Nov. 19, 2026

(54) Display Device And Electronic Device Comprising The Same

(71) Applicant: Samsung Display Co., Ltd., Yongin-si (KR)

(72) Inventors: Su Jeong Kim, Yongin-si (KR); Eui Jeong Kang, Yongin-si (KR); Hye Young Kim, Yongin-si (KR); See Ook Lee, Yongin-si (KR); Eun Jeong Jeon, Yongin-si (KR)

(73) Assignee: Samsung Display Co., Ltd., Yongin-si (KR)

(21) Appl. No.: 19/416,030

(22) Filed: Dec. 11, 2025

(30) Foreign Application Priority Data
May 13, 2025 (KR) 10-2025-0061788
Aug. 26, 2025 (KR) 10-2025-0119362

(51) Int. Cl. H10K 59/131; H10K 102/00

(52) U.S. Cl. CPC H10K 59/131; H10K 2102/311

(57) ABSTRACT

A display device includes a display panel including a main area, and a sub-area protruding from one side of the main area, an interlayer insulating film attached to the sub-area, a package element disposed on the interlayer insulating film, a circuit board attached to the interlayer insulating film, and a liner disposed on the interlayer insulating film. The interlayer insulating film includes a package area and a general area. The package element is disposed in the package area, and the package element includes a side surface extending in the second direction. The liner includes a liner adhesive portion adhered to the interlayer insulating film or the circuit board. The liner adhesive portion includes a side surface extending in the second direction, and the side surface of the liner adhesive portion may overlap the side surface of the package element in the first direction.

### CROSS-REFERENCE TO RELATED APPLICATIONS

This application claims priority to Korean Patent Application No. 10-2025-0061788 filed on May 13, 2025, and Korean Patent Application No. 10-2025-0119362 filed on Aug. 26, 2025, under 35 U.S.C. §119, the contents of each of which are herein incorporated by reference in their entirety.

### TECHNICAL FIELD

The present disclosure relates to a display device and an electronic device including the same.

### BACKGROUND

Electroluminescence displays may be divided into inorganic light emitting displays and organic light emitting displays depending on the material of a light emitting layer. An organic light emitting display of an active matrix type includes an organic light emitting diode (hereinafter, referred to as “OLED”) that emits light by itself, and has the advantages of a fast response speed, high emission efficiency, high brightness, and large viewing angle. The organic light emitting display has the organic light emitting diode (OLED) formed in each pixel. The organic light emitting display not only has a fast response speed and excellent emission efficiency, brightness, and viewing angle, but also has excellent contrast ratio and color reproducibility because the organic light emitting display may express black gradations as complete black.

### SUMMARY

Aspects of the present disclosure provide a display device having improved reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to various aspects of the disclosure, a display device includes a display panel including a main area extending in a first direction and a second direction intersecting the first direction, and a sub-area protruding in the second direction from one side of the main area, an interlayer insulating film attached to the sub-area, a package element disposed on the interlayer insulating film, a circuit board attached to the interlayer insulating film, and a liner disposed on the interlayer insulating film, wherein the interlayer insulating film includes a package area and a general area disposed in the first direction from the package area, the package element is disposed in the package area, the package element includes a side surface extending in the second direction, the liner includes a liner adhesive portion adhered to the interlayer insulating film or the circuit board, the liner adhesive portion includes a side surface extending in the second direction, and the side surface of the liner adhesive portion may overlap the side surface of the package element in the first direction.

According to various aspects of the disclosure, the package area has a first length in the second direction, the general area has a second length in the second direction, and the first length may be the same as the second length.

According to various aspects of the disclosure, the liner adhesive portion may overlap the general area in a thickness direction of the display panel.

According to various aspects of the disclosure, the interlayer insulating film may further include a first test pad and a second test pad disposed in the general area.

According to various aspects of the disclosure, the liner adhesive portion may be disposed between the first test pad and the second test pad in the first direction.

According to various aspects of the disclosure, in a bent form, the first test pad is disposed so as to be spaced apart from the main area by a first height, in the bent form, the second test pad is disposed so as to be spaced apart from the main area by a second height, and the first height may be the same as the second height.

According to various aspects of the disclosure, the package area has a first length in the second direction, the general area has a second length in the second direction, and the first length may be different from the second length.

According to various aspects of the disclosure, the circuit board includes a first extension area extending in the first direction and overlapping the general area in the second direction, and a second extension area extending in the first direction and overlapping the package area in the second direction, and the liner adhesive portion may overlap the first extension area in a thickness direction of the display panel.

According to various aspects of the disclosure, the circuit board may further include a first test pad and a second test pad disposed in the first extension area.

According to various aspects of the disclosure, the liner adhesive portion may be disposed between the first test pad and the second test pad in the first direction.

According to various aspects of the disclosure, in a bent form, the first test pad is disposed so as to be spaced apart from the main area by a first height, in the bent form, the second test pad is disposed so as to be spaced apart from the main area by a second height, and the first height may be the same as the second height.

According to various aspects of the disclosure, the liner adhesive portion may include a first liner adhesive portion overlapping the interlayer insulating film and the circuit board in a thickness direction of the display panel.

According to various aspects of the disclosure, the circuit board includes a first extension area extending in the first direction and overlapping the general area in the second direction, and a second extension area extending in the first direction and overlapping the package area in the second direction, and the liner adhesive portion may further include a second liner adhesive portion overlapping the first extension area in the thickness direction of the display panel.

According to various aspects of the disclosure, the liner adhesive portion may further include a third liner adhesive portion overlapping the general area in the thickness direction of the display panel.

According to various aspects of the disclosure, an electronic device includes a processor configured to provide an image signal, a display module configured to receive the image signal from the processor and display an image, and a power module configured to supply power to the display module, wherein the display module includes a display panel including a main area extending in a first direction and a second direction intersecting the first direction, and a sub-area protruding in the second direction from one side of the main area, an interlayer insulating film attached to the sub-area, a package element disposed on the interlayer insulating film, a circuit board attached to the interlayer insulating film, and a liner disposed on the interlayer insulating film, the interlayer insulating film includes a package area and a general area disposed in the first direction from the package area, the package element is disposed in the package area, the package element includes a side surface extending in the second direction, the liner includes a liner adhesive portion adhered to the interlayer insulating film or the circuit board, the liner adhesive portion includes a side surface extending in the second direction, and the side surface of the liner adhesive portion may overlap the side surface of the package element in the first direction.

According to various aspects of the disclosure, the package area has a first length in the second direction, the general area has a second length in the second direction, and the first length may be the same as the second length.

According to various aspects of the disclosure, the liner adhesive portion may overlap the general area in a thickness direction of the display panel.

According to various aspects of the disclosure, the package area has a first length in the second direction, the general area has a second length in the second direction, and the first length may be different from the second length.

According to various aspects of the disclosure, the circuit board includes a first extension area extending in the first direction and overlapping the general area in the second direction, and a second extension area extending in the first direction and overlapping the package area in the second direction, and the liner adhesive portion may overlap the first extension area in a thickness direction of the display panel.

According to various aspects of the disclosure, the liner adhesive portion may include a first liner adhesive portion overlapping the interlayer insulating film and the circuit board in a thickness direction of the display panel.

According to various aspects disclosed herein, as the area of the liner adhesive portion relatively increases, mechanical stability in the bending process may be secured, a stress distribution effect may be implemented, and in the long term, process reliability and operational reliability of the display device may be improved.

### BRIEF DESCRIPTION OF THE DRAWINGS

The above and other features of the present disclosure will become more apparent by describing in detail aspects thereof with reference to the attached drawings, in which:

FIG. 1 is a perspective view illustrating an electronic device according to an aspect of the present specification;

FIG. 2 is an exploded perspective view illustrating the electronic device of FIG. 1 according to an aspect of the present specification;

FIG. 3 is a plan view illustrating a display device according to an aspect of the present specification;

FIG. 4 is a cross-sectional view illustrating a portion cut along the line X1-X1’ of FIG. 3;

FIG. 5 is a block diagram illustrating a display device according to an aspect of the present specification;

FIG. 6 is a plan view illustrating a state in which a display device according to an aspect of the present specification is not bent;

FIG. 7 is a plan view illustrating a state in which the display device according to an aspect of the present specification is bent;

FIG. 8 is a plan view illustrating a state in which the conventional display device is bent;

FIG. 9 is a partial enlarged view illustrating area J of FIG. 7;

FIG. 10 is a cross-sectional view illustrating a portion cut along the line Y1-Y1’ of FIG. 7;

FIG. 11 is a cross-sectional view illustrating a portion cut along the line Y2-Y2’ of FIG. 7;

FIG. 12 is a partial enlarged view illustrating area K of FIG. 11;

FIG. 13 is a plan view illustrating a state in which a display device according to a first aspect of the present specification is not bent;

FIG. 14 is a plan view illustrating a state in which the display device according to the first aspect of the present specification is bent;

FIG. 15 is a partial enlarged view illustrating area L of FIG. 14;

FIG. 16 is a cross-sectional view illustrating a portion cut along the line Z1-Z1’ of FIG. 15;

FIG. 17 is a partial enlarged view illustrating area M of FIG. 15;

FIG. 18 is a plan view illustrating a state in which a display device according to a second aspect of the present specification is bent;

FIGS. 19 and 20 are partial enlarged views illustrating area N of FIG. 18;

FIG. 21 is a cross-sectional view illustrating a portion cut along the line W1-W1’ of FIG. 19;

FIG. 22 is a plan view illustrating a state in which a display device according to a third aspect of the present specification is bent;

FIG. 23 is a partial enlarged view illustrating area O of FIG. 22;

FIG. 24 is a cross-sectional view illustrating a portion cut along the line Q1-Q1’ of FIG. 23;

FIG. 25 is a cross-sectional view illustrating a portion cut along the line Q2-Q2’ of FIG. 23;

FIG. 26 is a cross-sectional view illustrating a portion cut along the line Q3-Q3’ of FIG. 23;

FIG. 27 is a block diagram of an electronic display device according to an aspect of the present specification; and

FIG. 28 illustrates schematic diagrams of electronic devices according to various aspects of the present specification.

### DETAILED DESCRIPTION

The advantages and features of the aspects disclosed herein, and methods of achieving them, will become apparent upon reference to the aspects described in detail with accompanying drawings. However, the present disclosure is not limited to the aspects disclosed herein, but may take many different forms, and these aspects are provided merely to make the disclosure complete and to fully inform one of ordinary skill in the art to which the present disclosure belongs, and the technical features according to the present disclosure are defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate aspects are exemplary and are not intended to be limiting to those shown herein.

Although first, second, and the like are used to describe various components, the components are not limited by these terms. Thus, a first component referred to herein may also be a second component within the technical idea of the present disclosure.

Each of the features of the various aspects disclosed herein may be combined or combinable with each other, in part or in whole, and may be technically interlocked and operated in a variety of ways, and each aspect may be practiced independently of or in conjunction with one another.

Specific aspects will be described below with reference to the accompanying drawings. Configurations that function substantially the same between aspects are given the same drawing designation and repeated description is omitted.

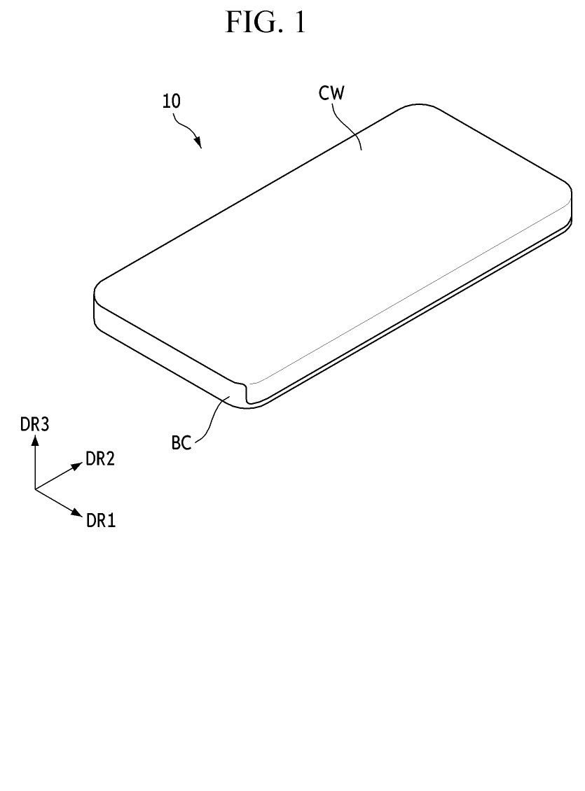

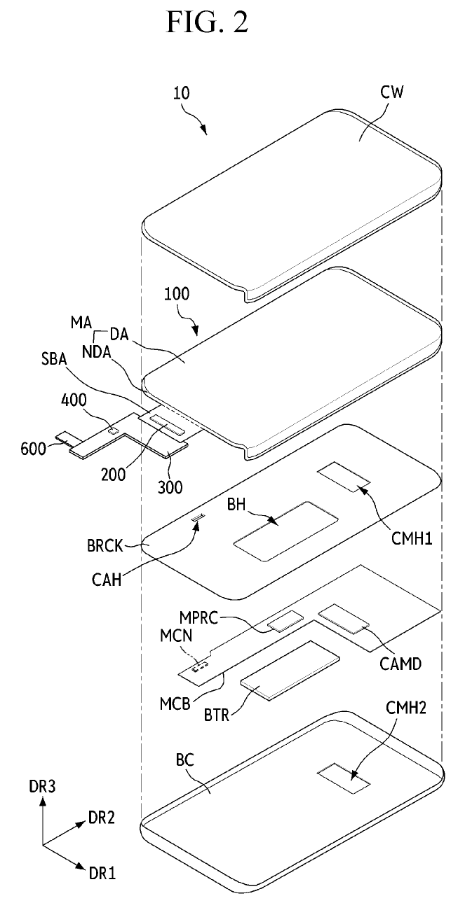

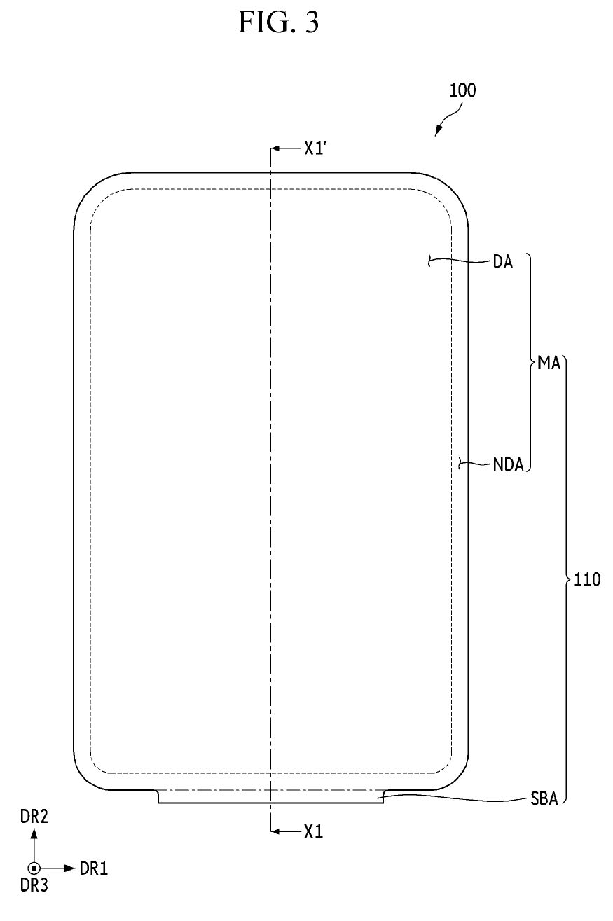

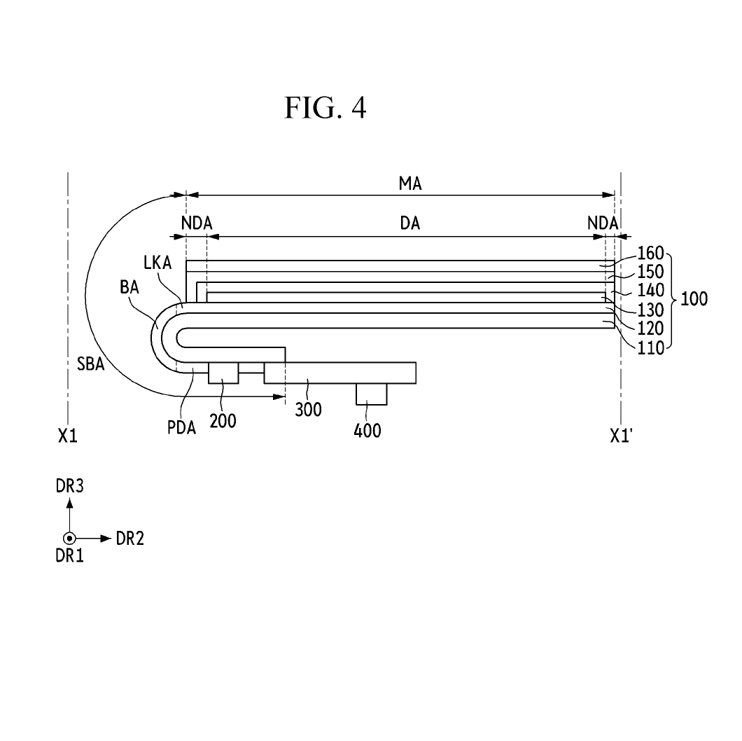

FIG. 1 is a perspective view illustrating an electronic device according to an aspect of the present specification. FIG. 2 is an exploded perspective view illustrating the electronic device of FIG. 1 according to an aspect of the present specification. FIG. 3 is a plan view illustrating a display device according to an aspect of the present specification. FIG. 4 is a cross-sectional view illustrating a portion cut along the line X1-X1’ of FIG. 3.

Referring to FIGS. 1-4, an electronic device 10 according to an aspect is a device having a function of displaying an image on a display area. The electronic device 10 may provide portability. As an example, the electronic device 10 may be a portable electronic device such a as mobile phone, a smartphone, a tablet personal computer (PC), a smart watch, a watch phone, a mobile communication terminal, an electronic notebook, an electronic book, a portable multimedia player (PMP), navigation, or a ultra mobile PC (UMPC). However, the electronic device 10 according to an aspect is not limited to the portable electronic device, and may be a large device such as a television, a laptop, a monitor, a billboard, or an Internet of Things (IoT).

The electronic device 10 according to an aspect may include a cover window CW and a lower cover BC provided as a housing that protects a display device 100.

The electronic device 10 may further include a display device 100, a bracket BRCK, and a main circuit board MCB accommodated between the cover window CW and the lower cover BC.

The display device 100 may include a main area MA including a display area DA where an image display is implemented, and a non-display area NDA around the display area DA, and a sub-area SBA protruding from one side of the main area MA.

The display device 100 may further include a display driving circuit 200 disposed in the sub-area SBA, a display circuit board 300 bonded to one side of the sub-area SBA, a touch driving circuit 400 mounted on the display circuit board 300, and a cable 600 extending from one side of the display circuit board 300.

In the present specification, a first direction DR1 may be a direction parallel to a short side of the electronic device 10 in plan view, for example, a horizontal direction of the electronic device 10. A second direction DR2 may be a direction parallel to a long side of the electronic device 10 in plan view, for example, a vertical direction of the electronic device 10. A third direction DR3 (or a thickness direction) may be a thickness direction of the electronic device 10.

The electronic device 10 may be formed in a shape similar to a rectangle in plan view. For example, the electronic device 10 may have a rectangular planar shape having short sides in the first direction DR1 and long sides in the second direction DR2. A corner where the short side in the first direction DR1 and the long side in the second direction DR2 meet may be rounded to have a curvature or may be formed at a right angle. The planar shape of the electronic device 10 is not limited to the rectangle, and may be formed into another polygon, circle, or ellipse.

The cover window CW may be disposed on an upper portion of the display device 100 so as to cover an upper surface of the display device 100. The cover window CW may serve to protect the upper surface of the display device 100.

The display device 100 may be disposed below the cover window CW. The display device 100 may include an upper surface portion facing an upper surface portion of the cover window CW, a left side surface portion facing a left side surface portion of the cover window CW, and a right side surface portion facing a right side surface portion of the cover window CW. The left side surface portion of the display device 100 may extend from a left side of the upper surface portion, and the right side surface portion thereof may extend from a right side of the upper surface portion.

The display device 100 may include a main area MA corresponding to a display surface and a sub-area SBA protruding from at least a portion of one side of the main area MA.

The main area MA may include a display area DA that displays an image and a non-display area NDA which is a peripheral area of the display area DA. The non-display area NDA may be disposed outside the display area DA. The non-display area NDA may be an edge area of the main area MA.

The sub-area SBA may protrude from one side of the main area MA in the second direction DR2. A length of the sub-area SBA in the first direction DR1 may be equal to or less than a length of the main area MA in the first direction DR1. A length of the sub-area SBA in the second direction DR2 may be smaller than a length of the main area MA in the second direction DR2, but is not limited thereto.

As a portion of the sub-area SBA is deformed in a bent shape, another portion of the sub-area SBA may overlap the main area MA in the third direction DR3 (or the thickness direction). The display driving circuit 200 may be mounted on the sub-area SBA, and the display circuit board 300 may be attached thereto.

One end of the display circuit board 300 may be attached to pads disposed on a lower edge of the sub-area SBA of the display device 100 using an anisotropic conductive film. The anisotropic conductive film may be formed to extend in the first direction DR1.

The display circuit board 300 may be a flexible printed circuit board (FPCB) that may be bent, a rigid printed circuit board (PCB) that maintains a flat shape, or a composite printed circuit board including both the rigid printed circuit board and the flexible printed circuit board.

The display driving circuit 200 may output data signals of data lines of a circuit layer disposed in the display area DA, based on control signals, powers, and voltages supplied through the display circuit board 300. The data signals may be transmitted to light emitting pixel drivers through the data lines.

The display driving circuit 200 may be provided as an integrated circuit (IC) and be mounted on the sub-area SBA of the display device 100 in a chip on glass (COG) manner, a chip on plastic (COP) manner, or an ultrasonic manner. However, this is merely an example and aspects of the present disclosure are not limited thereto. For example, the display driving circuit 200 may also be mounted on the display circuit board 300.

According to an aspect, a touch driving circuit 400 may be further mounted on the sub-area SBA of the display device 100. The touch driving circuit 400 may also be mounted on the display circuit board 300. The touch driving circuit 400 may be electrically connected to a touch sensor layer of the display device 100.

The bracket BRCK may be disposed below the display device 100. The bracket BRCK may include plastic or metal. The bracket BRCK may include a first camera hole CMH1 into which a camera device CAMD is inserted, a battery hole BH in which a battery BTR is disposed, and a cable hole CAH through which a cable 600 connected to the display circuit board 300 passes. A main circuit board MCB and a battery BTR may be disposed below the bracket BRCK.

The main circuit board MCB may be a printed circuit board or a flexible printed circuit board. The main circuit board MCB may include a main processor MPRC, a camera device CAMD, and a main connector MCN. The main processor MPRC may be formed as an integrated circuit. The main processor MPRC may control all functions of the electronic device 10. For example, the main processor MPRC may output digital video data to the display driving circuit 200 through the display circuit board 300 so that the display device 100 displays an image. In addition, the main processor MPRC may receive touch data including touch coordinates of a user from the touch driving circuit 400, determine whether the user has touched or is in proximity, and then execute an operation corresponding to a touch input or proximity input of the user. For example, the main processor MPRC may execute an application or perform an operation indicated by an icon touched by the user. The main processor MPRC may be an application processor, a central processing unit, or a system chip formed as an integrated circuit. Furthermore, the main circuit board MCB may be further equipped with a mobile communication module capable of transmitting and receiving wireless signals with at least one of a base station, an external terminal, and a server over a mobile communication network. The wireless signals may include various forms of data, such as voice signals, video call signals, or text/multimedia message transmission and reception.

The camera device CAMD may be disposed on both the upper and lower surfaces of the main circuit board MCB, the main processor MPRC may be disposed on the upper surface of the main circuit board MCB, and the main connector MCN may be disposed on the lower surface of the main circuit board MCB. The camera device CAMD processes image frames, such as still images or moving images, obtained by an image sensor in a camera mode and outputs the processed image frames to the main processor MPRC.

The cable 600 passing through the cable hole CAH of the bracket BRCK may be connected to the main connector MCN. As a result, the main circuit board MCB may be electrically connected to the display circuit board 300.

The battery BTR may be disposed so as not to overlap the main circuit board MCB in the third direction DR3 (or the thickness direction). The battery BTR may overlap the battery hole BH of the bracket BRCK in the third direction DR3 (or the thickness direction).

The lower cover BC may be disposed below the main circuit board MCB and the battery BTR. The lower cover BC may be fixed by being fastened to the bracket BRCK. The lower cover BC may form an upper side surface, a lower side surface, and a lower surface of the electronic device 10. The lower cover BC may include plastic, metal, or both the plastic and metal. The lower cover BC may include a second camera hole CMH2 through which a lower surface of the camera device CAMD is exposed. The position of the camera device CAMD and the positions of the first camera hole CMH1 and the second camera hole CMH2 corresponding to the camera device CAMD are not limited to those illustrated.

The display device 100 may be a light emitting display device such as an organic light emitting display device using an organic light emitting diode, a quantum dot light emitting display device including a quantum dot light emitting layer, an inorganic light emitting display device including an inorganic semiconductor, or a micro or nano light emitting display device using a micro or nano light emitting diode (micro or nano LED). Hereinafter, the description will be mainly made based on the fact that the display device 100 is an organic light emitting display device. However, the present disclosure is not limited thereto and may be applied to a display device including an organic insulating material, an organic light emitting material, and a metal material.

The display device 100 may be formed to be flat, but is not limited thereto. For example, the display device 100 may include curved surface portions formed at left and right distal ends thereof and having a constant curvature or a variable curvature. In addition, the display device 100 may be flexibly formed to be curved, bent, folded, or rolled.

The sub-area SBA may include a bending area BA that is deformed into a bent shape, a link area LKA disposed between one side of the bending area BA and the main area MA, and a pad area PDA connected to the other side of the bending area BA. When the bending area BA is deformed into the bent shape, the pad area PDA may be disposed on a rear surface of the display device 100 and may overlap the main area MA in the third direction DR3 (or the thickness direction).

According to an aspect, the display device 100 may include a substrate 110, a circuit layer 120 disposed on the substrate 110, an element layer 130 disposed on the circuit layer 120, and an encapsulation layer 140 disposed on the element layer 130. The display device 100 may further include a touch sensor layer 150 disposed on the encapsulation layer 140. The display device 100 may further include a polarizing layer 160 disposed on the touch sensor layer 150 to reduce reflection of external light.

The display area DA may include light emitting areas from which light is emitted, and a non-light-emitting area disposed between the light emitting areas.

The sub-area SBA may include a bending area BA that is deformed into a bent shape, a link area LKA disposed between one side of the bending area BA and the main area MA, and a pad area PDA connected to the other side of the bending area BA.

The circuit layer 120 may include light emitting pixel drivers electrically connected to light emitting elements, and data lines that transmit data signals to the light emitting pixel drivers EPD. The element layer 130 may include light emitting elements each disposed in the light emitting areas. The encapsulation layer 140 may cover the element layer 130. The encapsulation layer 140 may include a structure in which two or more inorganic films and at least one organic film are alternately stacked. The touch sensor layer 150 may be disposed on the encapsulation layer 140 and correspond to the main area MA. The touch sensor layer 150 may include touch electrodes for sensing a touch of a person or object. The polarizing layer 160 is intended to prevent image visibility from being reduced due to reflection of external light by blocking external light reflected from the touch sensor layer 150, the encapsulation layer 140, the element layer 130, and the circuit layer 120 and interfaces therebetween.

The display driving circuit 200 may be mounted in the pad area PDA of the sub-area SBA of the substrate 110.

The display circuit board 300 may be connected to pads disposed in the pad area PDA of the sub-area SBA of the substrate 110. When the bending area BA is deformed into the bent shape, the display driving circuit 200 and the display circuit board 300 may be disposed below the substrate 110.

The display driving circuit 200 may be electrically connected to the data lines through data supply lines. The display driving circuit 200 may output the data signals of the light emitting pixel drivers to the data lines DL, based on the control signals and power voltages supplied from the display circuit board 300. One end of the display circuit board 300 may be attached and connected to the pads using an anisotropic conductive film.

The touch driving circuit 400 may be mounted on the display circuit board 300. The touch driving circuit 400 may be electrically connected to the touch sensor layer 150 of the display device 100. The touch driving circuit 400 may apply a touch driving signal to driving lines of the touch sensor layer 150 and receive a touch sensing signal from sensing lines. In addition, the touch driving circuit 400 may determine whether the user has touched or is in proximity by sensing changes in charge of capacitances based on the touch sensing signal.

The display circuit board 300 may be attached and connected to the pads. The pads may include data pads electrically connected to the display driving circuit 200 and constant voltage transmission pads that transmit a constant voltage.

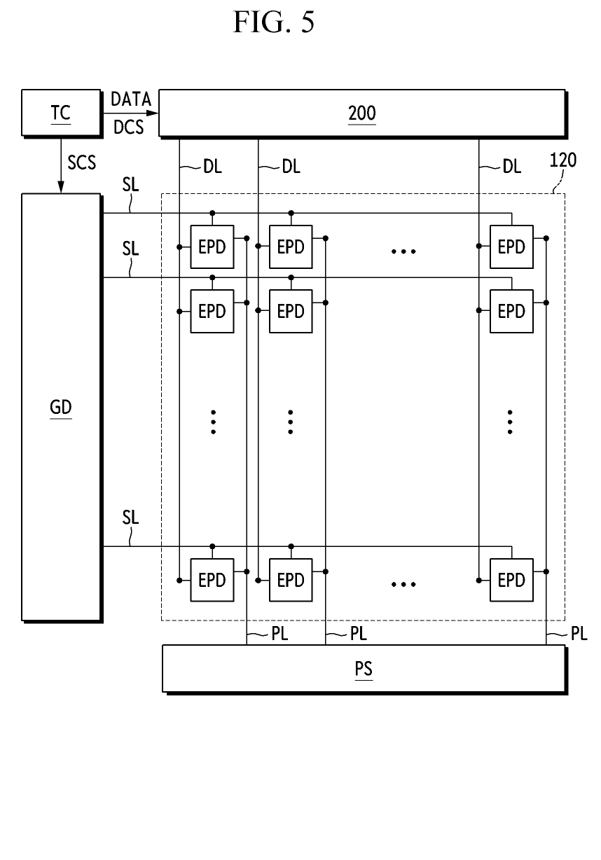

FIG. 5 is a block diagram illustrating a display device according to an aspect of the present specification.

Referring to FIG. 5, the circuit layer 120 of the display device according to an aspect may include light emitting pixel drivers EPD electrically connected to light emitting elements of an element layer, and data lines DL that transmit data signals to the light emitting pixel drivers EPD.

The circuit layer 120 may further include one or more scan lines SL that transmit one or more scan signals to the light emitting pixel drivers EPD.

According to an aspect, the display device may further include a display driving circuit 200 that outputs data signals corresponding to luminance of each of the light emitting elements to the data lines DL.

According to an aspect, the display device 100 may further include a gate driver GD that outputs scan signals to the scan lines SL, a power supply unit PS that supplies powers and voltages to the light emitting pixel drivers EPD, and a timing controller TC that controls a driving timing of each of the display driving circuit 200 and the gate driver GD.

The timing controller TC receives an image signal supplied from the outside of the display device. The timing controller TC may output image data DATA and a data control signal DCS to the display driving circuit 200. The timing controller TC may generate a scan control signal SCS for controlling an operation timing of the gate driver GD.

The display driving circuit 200 may convert the image data DATA into analog data voltages and output the analog data voltages to the data lines DL.

The gate driver GD may generate scan signals according to the scan control signal SCS and sequentially output the scan signals to the scan lines SL. The scan signals may have pulses that vary with a first gate level voltage or a second gate level voltage.

The power supply unit PS may supply various powers and voltages necessary for driving the light emitting pixel drivers EPD. As an example, the power supply unit PS may supply constant voltages such as a first power and a second power for generating driving signals of the light emitting elements, a gate initialization voltage and a bias voltage for initializing the light emitting pixel drivers EPD, and an anode initialization voltage for initializing the light emitting elements.

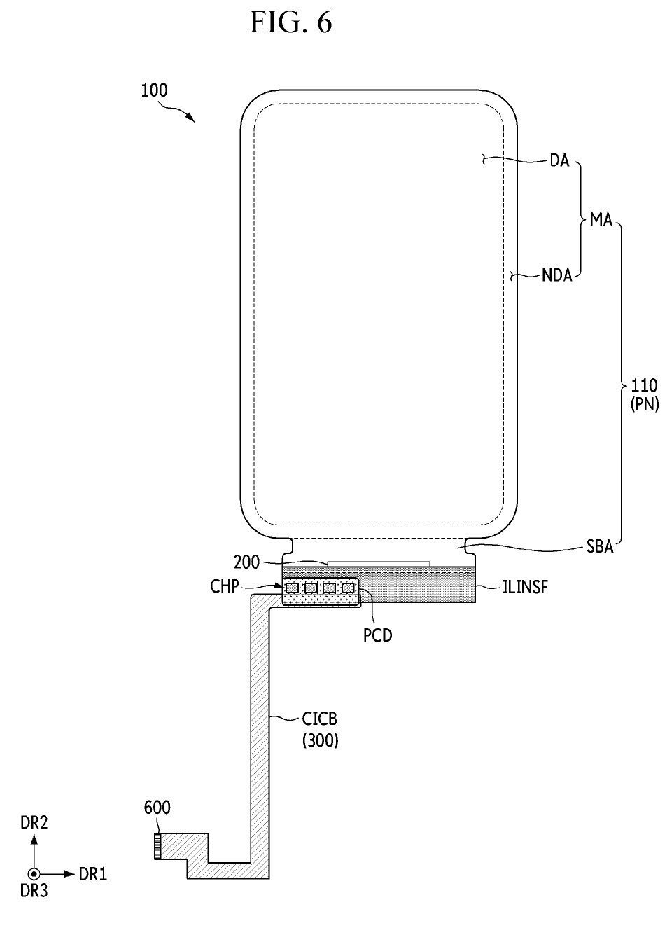

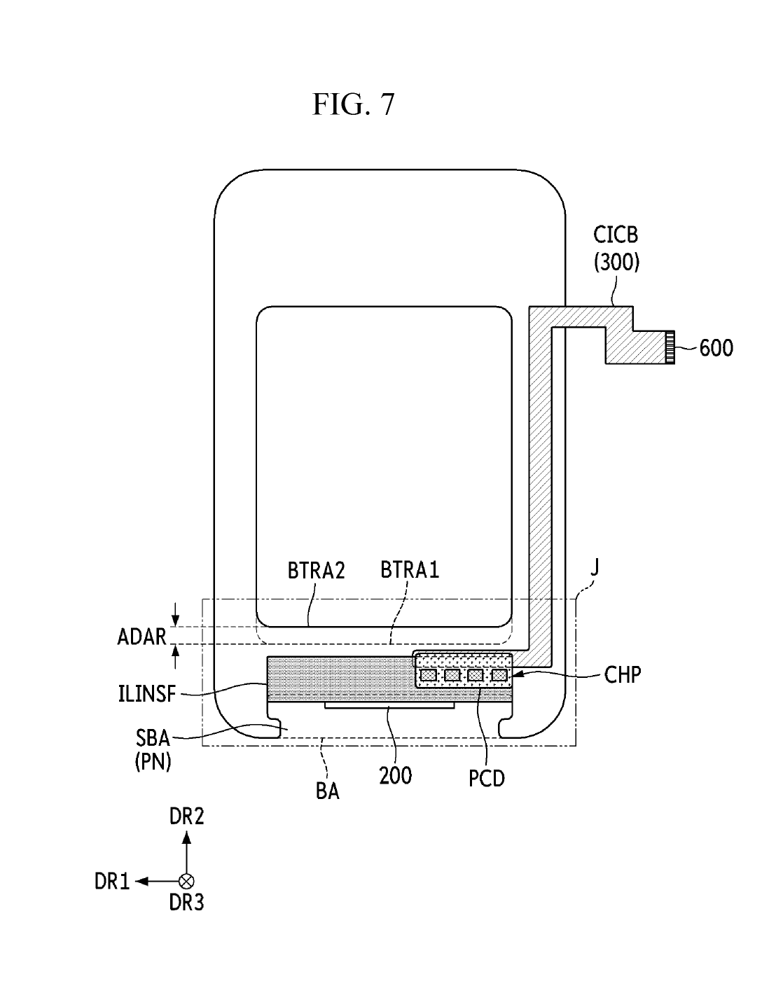

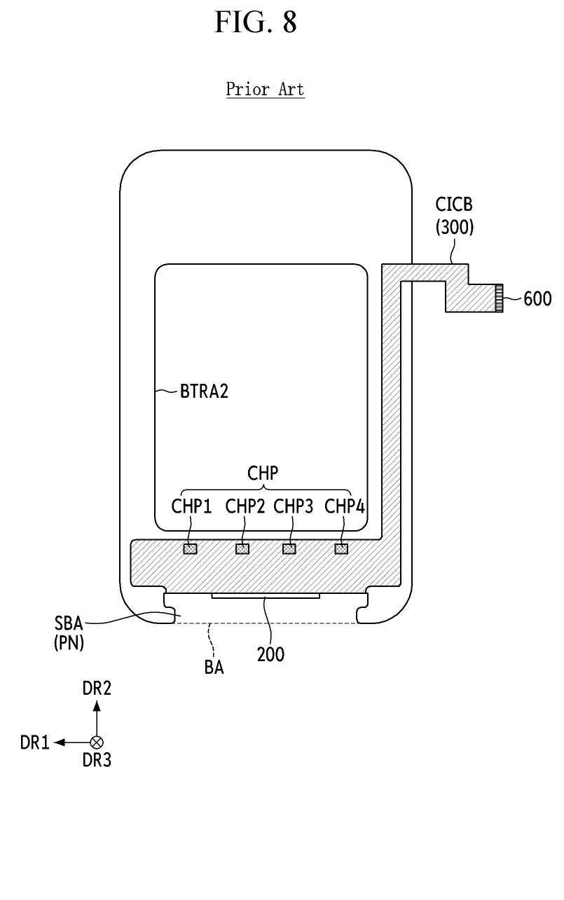

FIG. 6 is a plan view illustrating a state in which a display device according to an aspect of the present specification is not bent. FIG. 7 is a plan view illustrating a state in which the display device according to an aspect of the present specification is bent. FIG. 8 is a plan view illustrating a state in which the conventional display device is bent.

Referring to FIGS. 6-8, a display device according to an aspect of the present specification may include a display panel PN, a display driving circuit 200, an interlayer insulating film ILINSF, a package element PCD, a circuit board CICB (or a display circuit board 300), and a connector 600. The display panel PN may include a main area MA and a sub-area SBA. The main area MA may include a display area DA and a non-display area NDA.

The display panel PN may be electrically connected to the package element PCD and the circuit board CICB (or the display circuit board 300) through the interlayer insulating film ILINSF. The interlayer insulating film ILINSF may be attached to the sub-area SBA of the display panel PN through bonding areas BONA1 and BONA2. The interlayer insulating film ILINSF may be electrically connected to the package element PCD and the circuit board CICB (or the display circuit board 300).

The package element PCD may include a plurality of chips CHP. The package element PCD may be an element implemented by integrating multiple semiconductor chips CHP into a single package. Through the package element PCD, a complex system with the plurality of chips CHP may be implemented into a single small package.

For example, the package element PCD may include a plurality of chips CHP mounted on the conventional circuit board CICB (or display circuit board 300). The plurality of chips CHP may include, for example, a first chip CHP1, a second chip CHP2, a third chip CHP3, and a fourth chip CHP4. However, the number of chips CHP is not limited thereto. For example, the first chip CHP1 may be a touch driving circuit. The second chip CHP2 may be an analog-to-digital converter (ADC). The third chip CHP3 may be a microcontroller unit (MCU). The fourth chip CHP4 may be a memory chip CHP (e.g., a flash memory, etc.) or a power management integrated circuit (PMIC). In addition to the examples described above, the plurality of chips CHP may further include an interface chip CHP, a security chip CHP, a sensor compensation and calibration integrated circuits, etc., and the examples of chips CHP are not limited to those disclosed.

Implementing a system within a single package, such as the package element PCD, may be referred to as a system in package (SiP). Implementing the system within the package, such as the package element PCD, may save a space, reduce signal interference, and in some cases, enable optimized power management, because multiple functions are integrated into a single small package.

In the conventional display device depicted in FIG. 8, a space of the circuit board CICB (or the display circuit board 300) is formed to be relatively large, and the plurality of chips CHP are distributed and disposed in the relatively large space of the circuit board CICB (or the display circuit board 300). These may be connected to the display panel PN through an external line of the circuit board CICB. The conventional circuit board CICB (or display circuit board 300) has the advantage of being relatively simple in terms of manufacturing complexity and relatively easy in terms of replacement of individual components. However, the conventional circuit board CICB (or display circuit board 300) has a disadvantage in that it is difficult to secure battery capacity due to its relatively large size. For example, the conventional display device may have a second battery area BTRA2.

The display device according to an aspect of the present specification includes the package element PCD and electrically connects the package element PCD, the display panel PN, and the circuit board CICB (or, the display circuit board 300) to each other through the interlayer insulating film ILINSF. When a complex system is implemented through a single package element PCD, the circuit board CICB (or the display circuit board 300) may be miniaturized, and in particular, there is an advantage in that more space for physically disposing the battery may be secured. For example, the display device according to an aspect may have a first battery area BTRA1.

The first battery area BTRA1 has an additional battery area ADAR compared to the second battery area BTRA2. The space in which the battery may be disposed may be physically further secured through the additional battery area ADAR, and accordingly, a usage time of the display device may be improved. In addition, activation of high-performance functions and heat management of the display device may be made easier.

The display device according to an aspect of the present specification implements a structure in which the plurality of chips CHP are densely packed in a single package through the package element PCD including the plurality of chips CHP. Accordingly, the physical size of the circuit board CICB (or the display circuit board 300) may be reduced and the additional battery area ADAR may be secured.

When the display device includes the package element PCD, the display device according to an aspect may further include an interlayer insulating film ILINSF electrically connected to the package element PCD. The interlayer insulating film ILINSF may be electrically connected to the circuit board CICB (or the display circuit board 300) and the display panel PN.

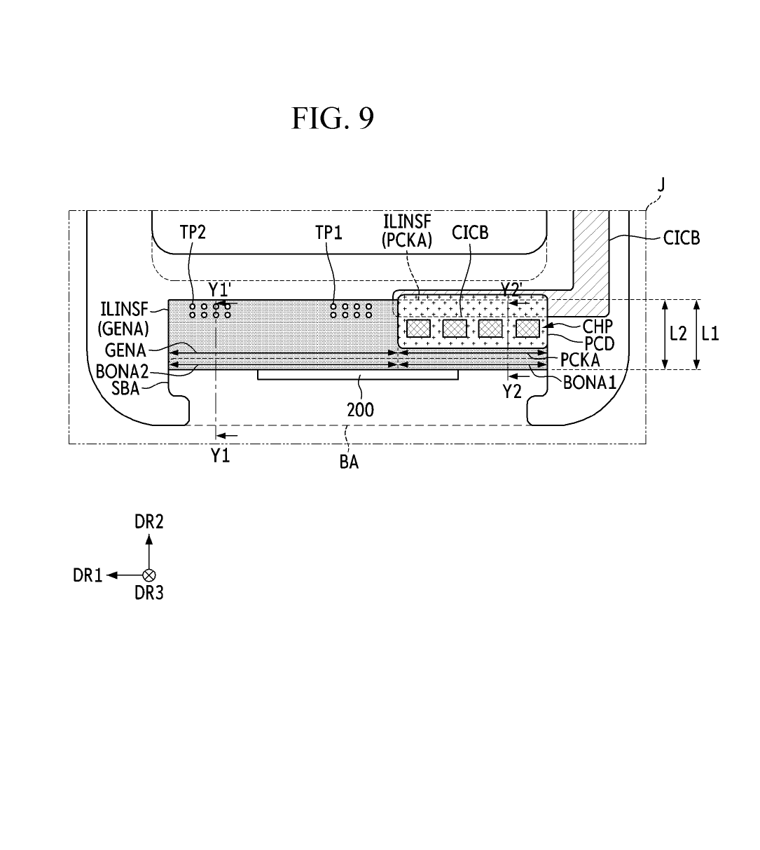

FIG. 9 is a partial enlarged view illustrating area J of FIG. 7.

Referring to FIG. 9, in the bent form, the sub-area SBA may be connected to the interlayer insulating film ILINSF through the bonding areas BONA1 and BONA2. The bonding areas BONA1 and BONA2 may be areas where the sub-area SBA and the interlayer insulating film ILINSF overlap in the third direction DR3 (or the thickness direction).

The interlayer insulating film ILINSF may be divided into a plurality of areas. The interlayer insulating film ILINSF may include a plurality of areas extending in the first direction DR1 and the second direction DR2. The interlayer insulating film ILINSF may include a package area PCKA extending in the first direction DR1 and the second direction DR2, and a general area GENA disposed in the first direction DR1 from the package area PCKA.

An area where the package area PCKA and the sub-area SBA overlap in the third direction DR3 (or the thickness direction) may be a first bonding area BONA1. An area where the general area GENA and the sub-area SBA overlap in the third direction DR3 (or the thickness direction) may be a second bonding area BONA2. The package area PCKA may be electrically connected to the sub-area SBA through the first bonding area BONA1, and the general area GENA may be electrically connected to the sub-area SBA through the second bonding area BONA2.

The package element PCD may be mounted or disposed in the package area PCKA. The package area PCKA may be distinguished from the general area GENA in that it includes the package element PCD. The circuit board CICB may be further connected to the package area PCKA.

In an aspect, the general area GENA and the package area PCKA may extend in the first direction DR1 and the second direction DR2.

The package area PCKA may have a first length L1 in the second direction DR2, and the general area GENA may have a second length L2 in the second direction DR2. The second length L2 may be the same as or different from the first length L1. In an aspect, the second length L2 may be the same as the first length L1.

The general area GENA may include a plurality of test pads TP1 and TP2. The test pads TP1 and TP2 may include a first test pad TP1 and a second test pad TP2 spaced apart from the first test pad TP1. The test pads TP1 and TP2 may be used to evaluate assembly reliability test (ART) between the interlayer insulating film ILINSF, the package element PCD, the sub-area SBA, and the circuit board CICB. That is, the test pads TP1 and TP2 may be portions where external probes (probe pins) come into contact to evaluate adhesion quality, contact stability, durability against heat and/or humidity, etc. after the interlayer insulating film ILINSF, the package element PCD, and the circuit board CICB are all assembled to be electrically connected. By disposing the test pads TP1 and TP2, deterioration and failure of the display device may be predicted, and an environmental stress test may be performed, thereby easily managing the quality of the display device.

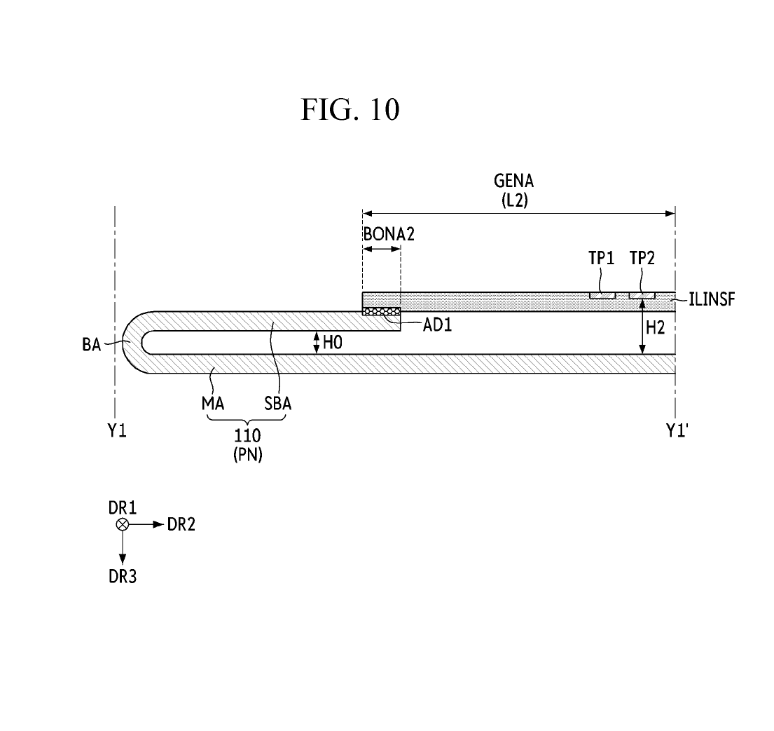

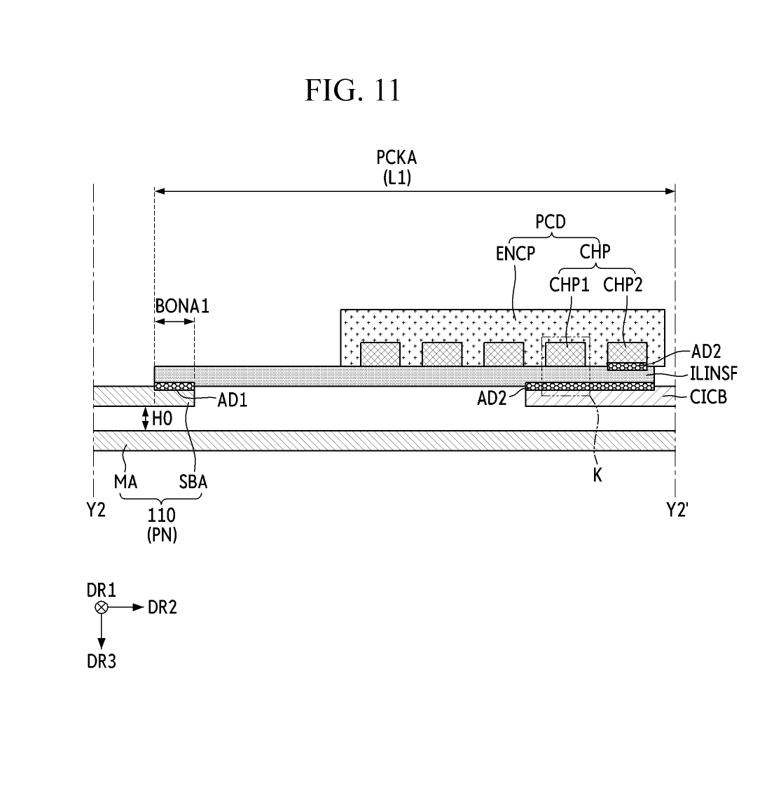

FIG. 10 is a cross-sectional view illustrating a portion cut along the line Y1-Y1’ of FIG. 7. FIG. 11 is a cross-sectional view illustrating a portion cut along the line Y2-Y2’ of FIG. 7.

Referring to FIGS. 9 and 10, in the bent form, the display panel PN may include a main area MA, a sub-area SBA, and a bending area BA connecting the main area MA and the sub-area SBA. In a space corresponding to a distance H0 between the main area MA and the sub-area SBA, a support member or the like that is in contact with the sub-area SBA and the main area MA and supports both of the sub-area SBA and the main area MA may be further disposed.

The sub-area SBA may be electrically connected to the interlayer insulating film ILINSF through a first adhesive member AD1. The cross-sectional view illustrated is a portion corresponding to the general area GENA of the interlayer insulating film ILINSF, and therefore, a length of the interlayer insulating film ILINSF in the second direction DR2 may be the second length L2. The first adhesive member AD1 may include an anisotropic conductive film (ACF). The first adhesive member AD1 may be disposed in the second bonding area BONA2 to fix the interlayer insulating film ILINSF to the sub-area SBA.

The second test pad TP2 may be disposed at a distance spaced from the main area MA by a second height H2. Although not illustrated, the first test pad TP1 may be disposed at a distance spaced from the main area MA by a first height. In an aspect, the first height and the second height H2 may be equal to each other. In the display device according to the aspects of the present specification, the first test pad TP1 and the second test pad TP2 may be formed to be positioned at the same distance from the main area MA.

If the first test pad TP1 and the second test pad TP2 are positioned at different heights, such as when the first test pad TP1 is disposed in the second bonding area BONA2, there is a possibility that an error may occur in the assembly reliability test due to a step difference between the first test pad TP1 and the second test pad TP2. The display device according to the aspect may improve the accuracy of the assembly reliability test by including the first test pad TP1 and the second test pad TP2 formed at the same height.

Referring to FIGS. 9 and 11, the sub-area SBA may be electrically connected to the interlayer insulating film ILINSF through the first adhesive member AD1. The cross-sectional view illustrated is a portion corresponding to the package area PCKA of the interlayer insulating film ILINSF, and therefore, a length of the interlayer insulating film ILINSF in the second direction DR2 may be the first length L1. The first adhesive member AD1 may include an anisotropic conductive film (ACF). The first adhesive member AD1 may be disposed in the first bonding area BONA1 to fix the interlayer insulating film ILINSF to the sub-area SBA.

The package element PCD may be disposed in the package area PCKA of the interlayer insulating film ILINSF. The package element PCD may be disposed on the interlayer insulating film ILINSF. The package element PCD may be disposed on one

surface of the interlayer insulating film ILINSF, and the circuit board CICB may be attached to the other surface of the interlayer insulating film ILINSF. In other words, the interlayer insulating film ILINSF may be disposed between the package element PCD and the circuit board CICB in the third direction DR3 (or the thickness direction).

The circuit board CICB may be electrically connected to the interlayer insulating film ILINSF through a second adhesive member AD2. The circuit board CICB may be attached to the interlayer insulating film ILINSF through the second adhesive member AD2. The second adhesive member AD2 may include a metal, but the aspects of the present specification are not limited thereto. In an aspect, the metal may include tin (Sn) and lead (Pb) or lead-free solder (Sn-Ag-Cu), but aspects of the present specification are not limited thereto. For example, the interlayer insulating film ILINSF and the circuit board CICB may be connected to each other through soldering. The soldering may be an attaching method that melts a metal to connect the interlayer insulating film ILINSF and the circuit board CICB. For example, the circuit board CICB may be connected to the interlayer insulating film ILINSF through soldering.

The package element PCD disposed on one surface of the interlayer insulating film ILINSF may include a plurality of chips CHP and an encapsulant ENCP. The plurality of chips CHP may include a first chip CHP1 and a second chip CHP2, and the aspects of the present specification are not limited thereto. In addition, the examples of the first chip CHP1 and the second chip CHP2 are not limited to those described above.

One chip CHP (e.g., the second chip CHP2) of the package element PCD may be connected to the interlayer insulating film ILINSF via the second adhesive member AD2, and another chip CHP (e.g., the first chip CHP1) may be electrically connected to the interlayer insulating film ILINSF through another connection method.

The encapsulant ENCP may be configured to seal and secure the plurality of chips CHP. The encapsulant ENCP may protect the plurality of chips CHP from external environments such as dust, moisture, and impact, perform a heat dissipation function by transferring heat emitted by the chips CHP during operation to the outside, prevent electrical interference between the chips CHP and the outside, and mechanically support the plurality of chips CHP to the interlayer insulating film ILINSF.

For example, the encapsulant ENCP may be an epoxy-based encapsulant. For example, the encapsulant ENCP may be an epoxy molding compound (EMC). The encapsulant ENCP may include an epoxy resin, which is a thermosetting polymer, a filler for improving thermal conductivity and mechanical strength, a curing agent for curing the epoxy resin, and additives for controlling adhesion, fluidity, moisture resistance, etc.

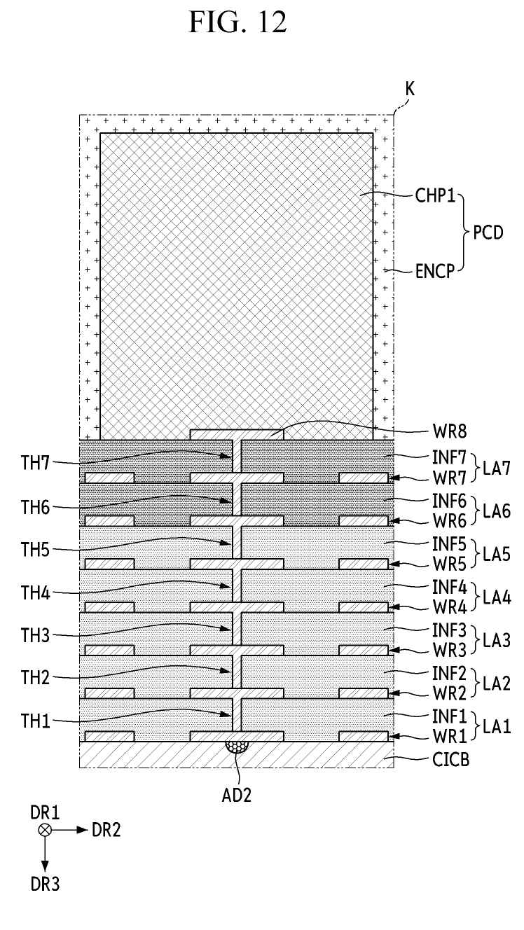

FIG. 12 is a partial enlarged view illustrating area K of FIG. 11.

Referring to FIGS. 11 and 12, the interlayer insulating film ILINSF may be electrically connected to the circuit board CICB through the second adhesive member AD2. The package element PCD may be disposed on the interlayer insulating film ILINSF, and the first chip CHP1 according to the aspects may be electrically connected to the interlayer insulating film ILINSF through another connection method described above.

The interlayer insulating film ILINSF may include circuit line layers LA1~LA7 including a plurality of line layers LA1, LA2, LA3, LA4, LA5, LA6, and LA7. The circuit line layers LA1~LA7 may include a plurality of line layers LA1, LA2, LA3, LA4, LA5, LA6, and LA7 for electrically connecting the sub-area SBA and the package element PCD, or the sub-area SBA and the circuit board CICB. The plurality of line layers LA1, LA2, LA3, LA4, LA5, LA6, and LA7 may include a first line layer LA1, a second line layer LA2, a third line layer LA3, a fourth line layer LA4, a fifth line layer LA5, a sixth line layer LA6, and a seventh line layer LA7, but the aspects of the present specification are not limited thereto.

Each of the plurality of line layers LA1, LA2, LA3, LA4, LA5, LA6, and LA7 may include wirings WR1, WR2, WR3, WR4, WR5, WR6, and WR7 and insulating films INF1, INF2, INF3, INF4, INF5, INF6, and INF7 covering the wirings WR1, WR2, WR3, WR4, WR5, WR6, and WR7. For example, the first line layer LA1 may include a first wiring WR1 and a first insulating film INF1 covering the first wiring WR1, the second line layer LA2 may include a second wiring WR2 and a second insulating film INF2 covering the second wiring WR2, the third line layer LA3 may include a third wiring WR3 and a third insulating film INF3 covering the third wiring WR3, the fourth line layer LA4 may include a fourth wiring WR4 and a fourth insulating film INF4 covering the fourth wiring WR4, the fifth line layer LA5 may include a fifth wiring WR5 and a fifth insulating film INF5 covering the fifth wiring WR5, the sixth line layer LA6 may include a sixth wiring WR6 and a sixth insulating film INF6 covering the sixth wiring WR6, and the seventh line layer LA7 may include a seventh wiring WR7 and a seventh insulating film INF7 covering the seventh wiring WR7. In this way, the circuit line layers LA1~LA7 may be formed in a structure in which multiple layers of wiring and insulating films are repeatedly stacked to implement a highly integrated circuit.

Each of the plurality of wirings WR1, WR2, WR3, WR4, WR5, WR6, and WR7 may include metal. For example, the plurality of wirings WR1, WR2, WR3, WR4, WR5, WR6, and WR7 may include copper. The plurality of wirings WR1, WR2, WR3, WR4, WR5, WR6, and WR7 may serve to transmit electrical signals in the circuit line layers LA1~LA7.

Each of the plurality of insulating films INF1, INF2, INF3, INF4, INF5, INF6, and INF7 may include an epoxy resin-based insulating material. Each of the plurality of insulating films INF1, INF2, INF3, INF4, INF5, INF6, and INF7 may serve to prevent electrical interference between the plurality of wirings WR1, WR2, WR3, WR4, WR5, WR6, and WR7 and prevent leakage current.

Each of the plurality of insulating films INF1, INF2, INF3, INF4, INF5, INF6, and INF7 includes a common material in that they all include an epoxy-based insulating material, but may also be divided into two groups of layers including different materials. In an aspect, the first insulating film INF1, the second insulating film INF2, the third insulating film INF3, the fourth insulating film INF4, and the fifth insulating film INF5 may include the same material, and the sixth insulating film INF6 and the seventh insulating film INF7 may include the same material. For example, the first insulating film INF1, the second insulating film INF2, the third insulating film INF3, the fourth insulating film INF4, and the fifth insulating film INF5 may include an epoxy-based resin, a curing agent, and inorganic fine particles. The sixth insulating film INF6 and the seventh insulating film INF7 may include an epoxy-based resin and glass fiber. The sixth insulating film INF6 and the seventh insulating film INF7 may include a prepreg (pre-impregnated composite). The prepreg is cured in response to heat and pressure and has excellent mechanical strength and electrical properties.

Through holes TH1, TH2, TH3, TH4, TH5, TH6, and TH7 may each be formed in the plurality of insulating films INF1, INF2, INF3, INF4, INF5, INF6, and INF7. For example, a first through hole TH1 may be formed in the first insulating film INF1, a second through hole TH2 may be formed in the second insulating film INF2, a third through hole TH3 may be formed in the third insulating film INF3, a fourth through hole TH4 may be formed in the fourth insulating film INF4, a fifth through hole TH5 may be formed in the fifth insulating film INF5, a sixth through hole TH6 may be formed in the sixth insulating film INF6, and a seventh through hole TH7 may be formed in the seventh insulating film INF7.

The plurality of wirings WR1, WR2, WR3, WR4, WR5, WR6, and WR7 may be electrically connected to each other through the through holes TH1, TH2, TH3, TH4, TH5, TH6, and TH7 formed in the plurality of insulating films INF1, INF2, INF3, INF4, INF5, INF6, and INF7, respectively. An eighth wiring WR8 may be further disposed on the seventh line layer LA7. The eighth wiring WR8 may electrically connect the package element PCD including the first chip CHP1 and the interlayer insulating film ILINSF to each other.

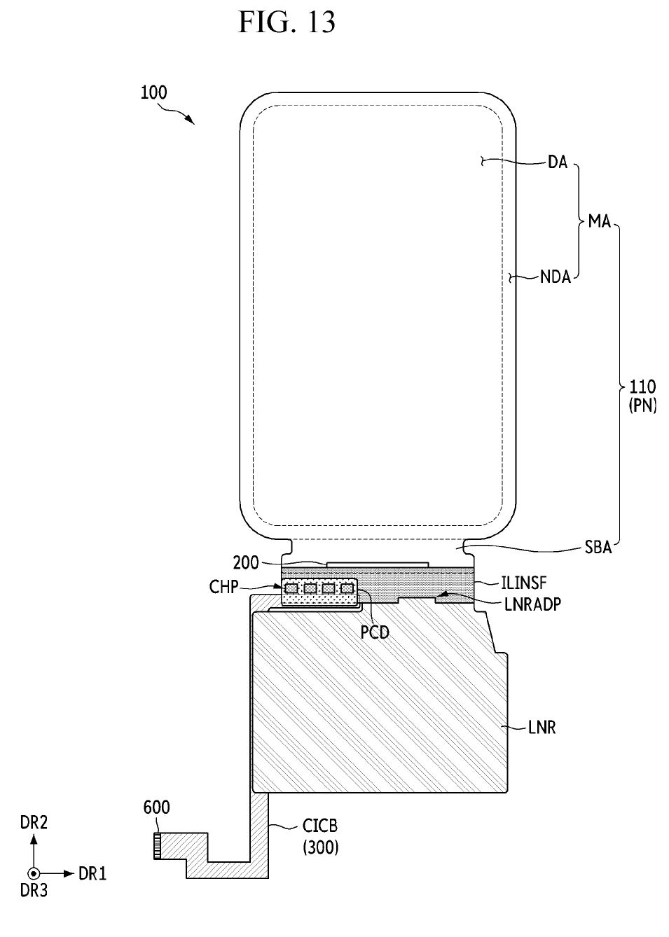

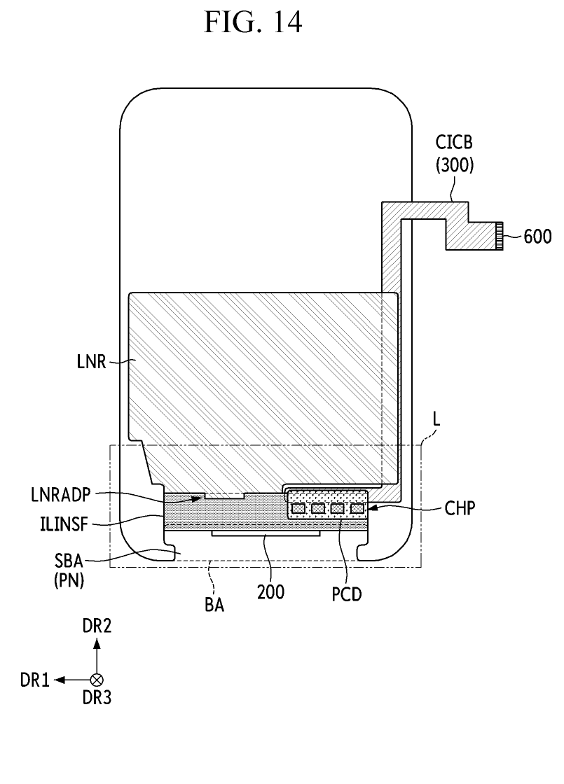

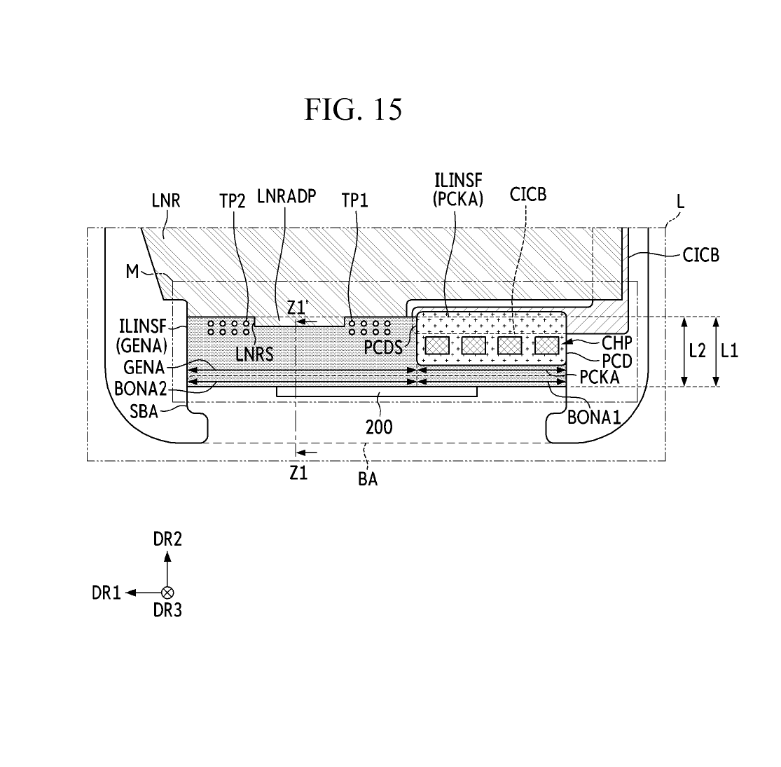

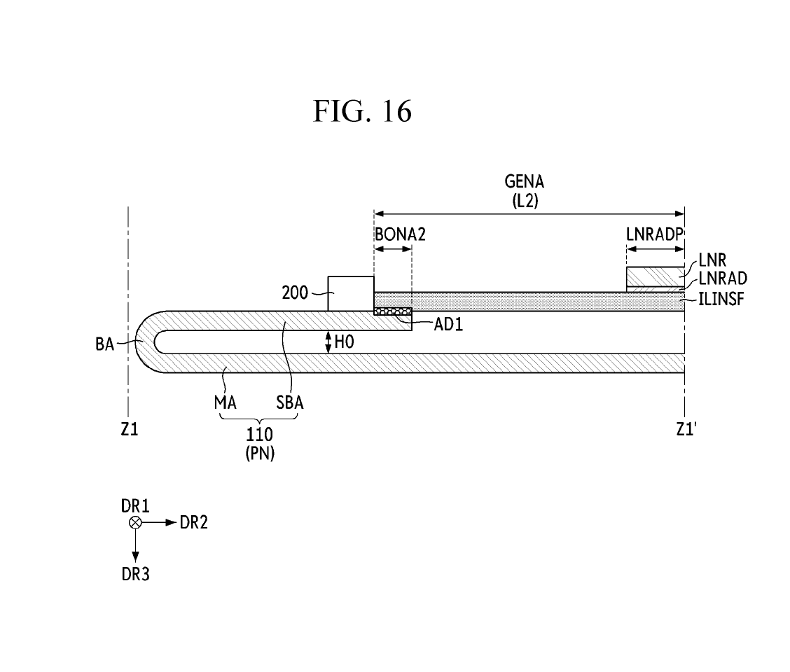

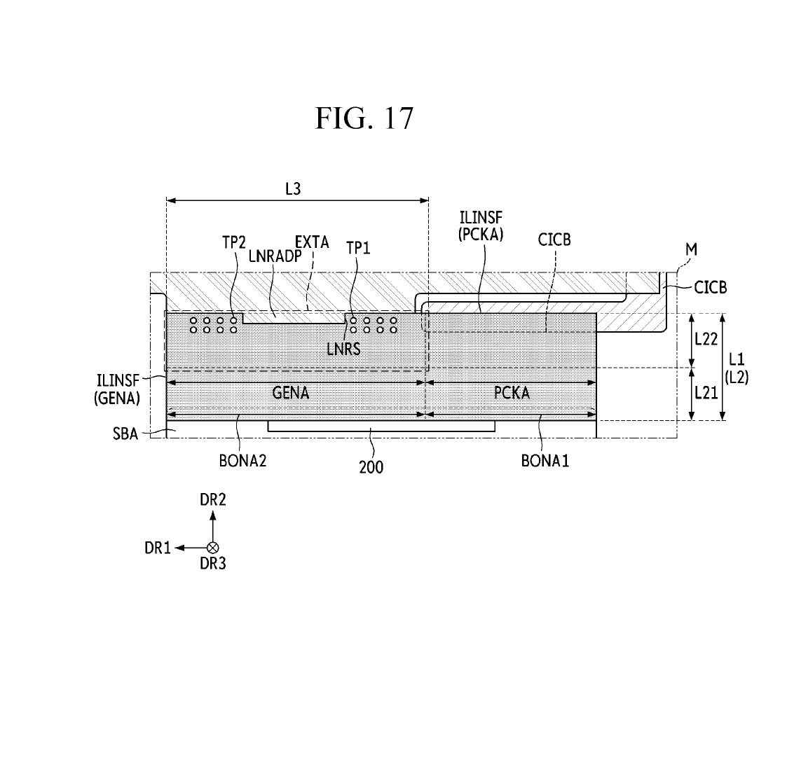

FIG. 13 is a plan view illustrating a state in which a display device according to a first aspect of the present specification is not bent. FIG. 14 is a plan view illustrating a state in which the display device according to the first aspect of the present specification is bent. FIG. 15 is a partial enlarged view illustrating area L of FIG. 14. FIG. 16 is a cross-sectional view illustrating a portion cut along the line Z1-Z1’ of FIG. 15. FIG. 17 is a partial enlarged view illustrating area M of FIG. 15.

Referring to FIGS. 13-15, a display device according to a first aspect may include a liner LNR.

A sub-area SBA of a display panel PN may be converted to a bent state during a process of manufacturing the display device. In the unbent state, the interlayer insulating film ILINSF to which the package element PCD and the circuit board CICB are attached may be attached to the sub-area SBA through an anisotropic conductive film, etc. The liner LNR may be used to protect the interlayer insulating film ILINSF, the circuit board CICB, and the package element PCD during the bending process.

The process of bending the sub-area SBA may affect structural integrity of the display panel PN, and in particular, the display panel PN may be damaged by external pressure or stress. Therefore, an auxiliary structure capable of protecting the display panel PN in the unbent state and maintaining precision during the process may be required.

The liner LNR may be attached to a designated surface in the state in which the display device is not bent to serve to protect the display panel PN from mechanical stress, pressure, or external impact that may occur during the bending process. The liner LNR may include a plastic resin, polyimide, or a polymer composite material. The liner LNR may be designed to have a constant thickness and elastic modulus.

Since the liner LNR serves to protect the circuit board CICB and the interlayer insulating film ILINSF during the bending process, it is necessary that it not be separated from the circuit board CICB and the interlayer insulating film ILINSF during the bending process. That is, the liner LNR according to an aspect may include a liner adhesive portion LNRADP that is adhered to the interlayer insulating film ILINSF or the circuit board CICB. The liner LNR may be fixed to the interlayer insulating film ILINSF and the circuit board CICB by the liner adhesive portion LNRADP.

When an area corresponding to the liner adhesive portion LNRADP is not sufficiently secured, problems such as displacement in position of the parts, lifting, or poor adhesion due to micro-vibrations during the bending or subsequent processes may occur, resulting in reduced mechanical fixing strength. In addition, when the area of the liner adhesive portion LNRADP is relatively small, the stress caused by the bending process may be locally concentrated, which may cause excessive pressure to be applied to a specific area of the circuit board or the interlayer insulating film ILINSF. This may cause problems such as microcircuit pattern damage, solder cracks, or microcircuit short circuits. In addition, yield problems may occur, such as reduced consistency between the processes and product deviation in the display device, as attachment stability of the liner LNR is relatively reduced.

In the display device including the package element PCD, the present specification may sufficiently secure the area of the liner adhesive portion LNRADP that is adhered to the interlayer insulating film ILINSF or the circuit board CICB. According to various aspects disclosed in the present specification, as the area of the liner adhesive portion relatively increases, mechanical stability in the bending process may be secured, a stress distribution effect may be implemented, and in the long term, process reliability and operational reliability of the display device may be improved.

The area of the liner adhesive portion LNRADP needs to be secured as large as possible without damaging the components of the display device, such as the interlayer insulating film ILINSF, the package element PCD, and the circuit board CICB. An adhesive portion between the circuit board CICB and the liner LNR may extend in the second direction DR2. Since the circuit board CICB in the conventional display device is formed to extend in the second direction DR2, the liner LNR may provide mechanical stability due to adhesion to the circuit board extending in the second direction DR2.

If only the adhesive portion with the circuit board CICB extending in the second direction DR2 exists as described above, an asymmetry in a fixing force may occur because an adhesive portion extending in the first direction DR1 is absent.

In the bent state, the circuit board CICB extends in the second direction DR2 from one side (e.g., the right side) of the display panel PN, and accordingly, the adhesive portion extends in the second direction DR2 from one side of the display panel PN. In this case, a portion of the liner LNR disposed on the other side of the display panel PN may move or rotate in the third direction DR3 (or the thickness direction) and may not provide a sufficient fixing force. As a result, the liner LNR may become displaced or misaligned during the bending process.

The present specification may provide a display device including not only an adhesive portion with the circuit board CICB extending in the second direction DR2, but also a liner adhesive portion LNRADP with the interlayer insulating film ILINSF (or the circuit board CICB) extending in the first direction DR1. The liner LNR may be adhered not only to the circuit board CICB extending in the second direction DR2, but also to the interlayer insulating film ILINSF (or the circuit board CICB) extending in the first direction DR1.

Since the package element PCD includes the plurality of chips CHP as described above, a thickness thereof may be relatively much larger than that of the interlayer insulating film ILINSF or the circuit board CICB. It is not desirable to form the liner adhesive portion

LNRADP to overlap the package element PCD in the third direction DR3 (or the thickness direction) because this may result in a decrease in the fixing force due to a difference in the thickness.

The display device according to the first aspect may improve the fixing force of the liner LNR by extending the general area GENA in which the package element PCD is not disposed in the second direction DR2 and forming the liner adhesive portion LNRADP extending in the first direction DR1 in the extended general area GENA.

Referring to FIGS. 15-17, the display device in the bent state according to the first aspect may include an interlayer insulating film ILINSF adhered to the sub-area SBA, a package element PCD electrically connected to the interlayer insulating film ILINSF, and a circuit board CICB.

A general area GENA of the interlayer insulating film ILINSF may have a second length L2 in the second direction DR2, and a package area PCKA may have a first length L1 in the second direction DR2. According to aspects, the first length L1 and the second length L2 may be formed to be the same. The length of the general area GENA in the second direction DR2 may be extended to be equal to the first length L1. Accordingly, an extension area EXTA may be defined.

A length of the extension area EXTA in the second direction DR2 may be a second sub-length L22, and a liner adhesive portion LNRADP may be formed in the extension area EXTA. In an aspect, the liner adhesive portion LNRADP may include a side surface LNRS of the liner adhesive portion LNRADP extending in the second direction DR2. The package element PCD may include a side surface PCDS of the package element PCD extending in the second direction DR2. According to aspects of the present specification, the side surface LNRS of the liner adhesive portion LNRADP may overlap the side surface PCDS of the package element PCD in the first direction DR1.

The liner adhesive portion LNRADP may extend in the first direction DR1 and may be designed so as not to overlap the package element PCD in the third direction DR3 (or the thickness direction). It is preferable that the liner adhesive portion LNRADP extending in the first direction DR1 be formed to overlap the general area GENA.

In this case, the liner adhesive portion LNRADP may be formed adjacent to the display driving circuit 200 without forming the extension area EXTA, that is, in a state in which the length of the general area GENA in the second direction DR2 becomes a first sub-length L21. The liner adhesive portion LNRADP will extend in the first direction DR1 and the second direction DR2, and even in this case, the side surface LNRS of the liner adhesive portion LNRADP may overlap the side surface PCDS of the package element PCD in the first direction DR1.

The liner adhesive portion LNRADP of the display device according to the first aspect may be formed to overlap the extension area EXTA having the second sub-length L22 in the second direction DR2 in the third direction DR3 (or the thickness direction). The liner adhesive component LNRAD may be disposed between the interlayer insulating film ILINSF and the liner LNR in the third direction DR3 (or the thickness direction). If the liner adhesive portion LNRADP continues to extend in the second direction DR2 (i.e., continues to extend in the second direction DR2 so as to be adjacent to the display driving circuit 200 or the second bonding area BONA2), a problem may occur in that the manufacturing cost of the liner LNR that needs to be removed from the final product increases.

According to aspects of the present specification, a shape of the liner LNR may be designed to include a protrusion corresponding to the liner adhesive portion LNRADP, and a length of the protrusion in the second direction DR2 may be reduced to a minimum. At the same time, if an adhesive force is sufficiently secured by the liner adhesive portion LNRADP extended in the first direction DR1, the manufacturing cost of the liner LNR may be reduced. Additionally, since electrical connections may be additionally implemented within the interlayer insulating film ILINSF in the extension area EXTA, there is also an advantage in that electrical connections between more chips CHP and elements may be designed.

In some aspects, an assembly reliability evaluation by the test pads TP1 and TP2 may be performed with the liner LNR attached. For example, the evaluation may be performed after the bending process. In this case, the liner adhesive portion LNRADP may be formed between the first test pad TP1 and the second test pad TP2 in the first direction

DR1 so that the test pads TP1 and TP2 with which the probe is in direct contact are not covered by the liner LNR.

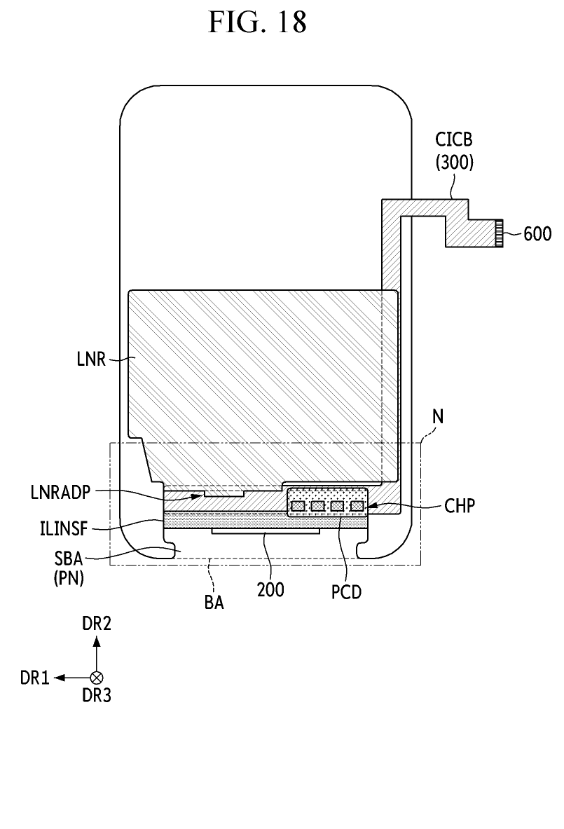

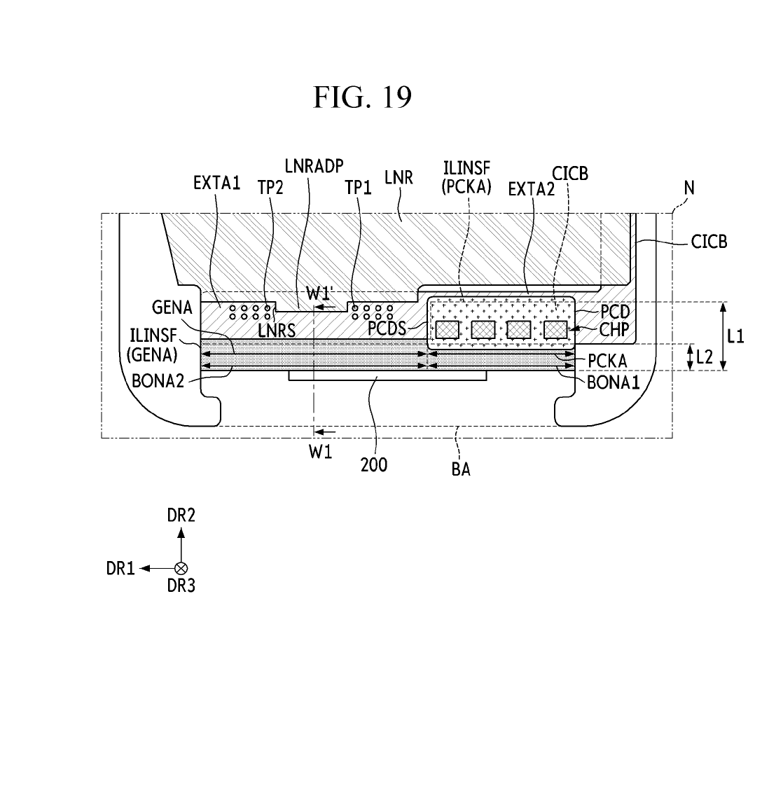

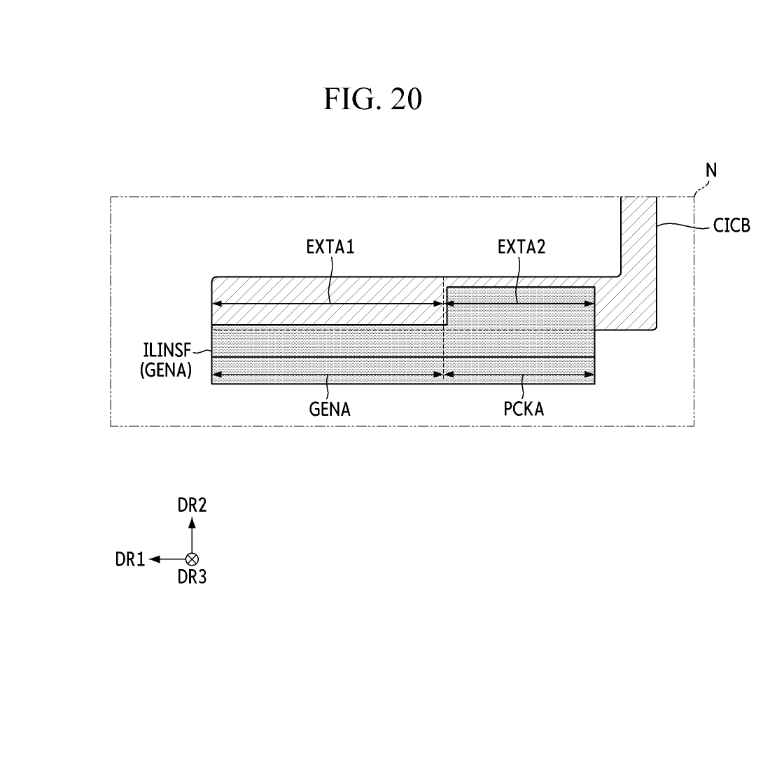

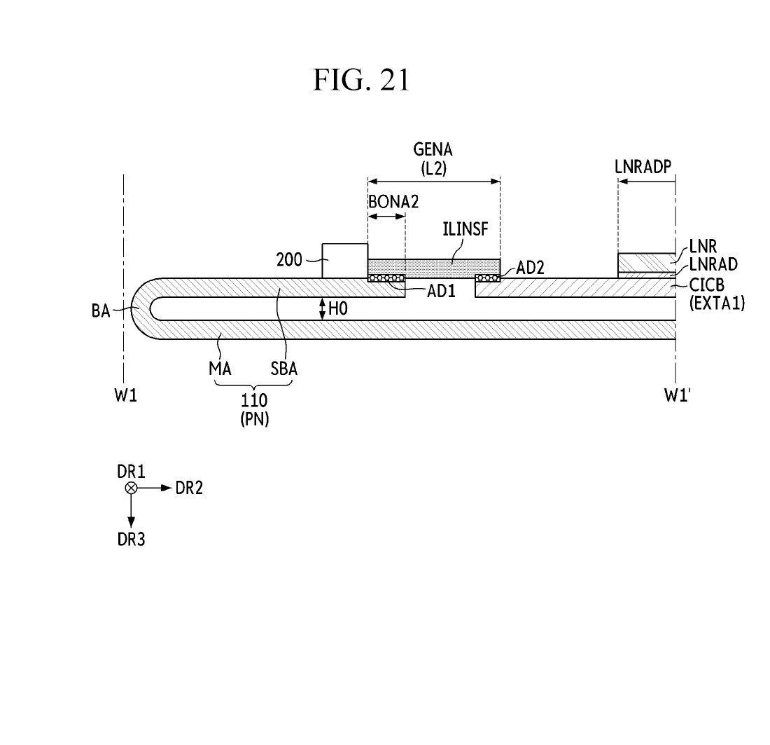

FIG. 18 is a plan view illustrating a state in which a display device according to a second aspect of the present specification is bent. FIGS. 19 and 20 are partial enlarged views illustrating area N of FIG. 18. FIG. 21 is a cross-sectional view illustrating a portion cut along the line W1-W1’ of FIG. 19.

Referring to FIGS. 18-21, the liner adhesive portion LNRADP extending in the first direction DR1 may be formed to overlap the circuit board CICB in the third direction DR3 (or the thickness direction). The circuit board CICB may include a first extension area EXTA1 and a second extension area EXTA2 extending in the first direction DR1. The second length L2, which is the length of the general area GENA in the second direction DR2, may be formed to be smaller than the first length L1, which is the length of the package area PCKA in the second direction DR2.

The first extension area EXTA1 may overlap the general area GENA in the second direction DR2. The second extension area EXTA2 may overlap the package area PCKA in the second direction DR2. The second extension area EXTA2 may also overlap the package area PCKA in the third direction DR3 (or the thickness direction). The liner adhesive portion LNRADP may be formed to overlap the first extension area EXTA1 in the third direction DR3 (or the thickness direction). The liner adhesive component LNRAD may be disposed between the circuit board CICB corresponding to the first extension area EXTA1 and the liner LNR in the third direction DR3 (or the thickness direction). In this case, since the side surface LNRS of the liner adhesive portion LNRADP extending in the second direction DR2 may overlap the side surface PCDS of the package element PCD extending in the second direction DR2 in the first direction DR1, which is similar to the first aspect described above, the detailed description thereof is omitted.

The interlayer insulating film ILINSF may be divided into a plurality of areas. The interlayer insulating film ILINSF may include a plurality of areas extending in the first direction DR1 and the second direction DR2. The interlayer insulating film ILINSF may include a package area PCKA extending in the first direction DR1 and the second direction

DR2, and a general area GENA disposed in the first direction DR1 from the package area PCKA.

An area where the package area PCKA and the sub-area SBA overlap in the third direction DR3 (or the thickness direction) may be a first bonding area BONA1. An area where the general area GENA and the sub-area SBA overlap in the third direction DR3 (or the thickness direction) may be a second bonding area BONA2. The package area PCKA may be electrically connected to the sub-area SBA through the first bonding area BONA1, and the general area GENA may be electrically connected to the sub-area SBA through the second bonding area BONA2.

The package element PCD may be mounted or disposed in the package area PCKA. The package area PCKA may be distinguished from the general area GENA in that it includes the package element PCD. The circuit board CICB may be further connected to the package area PCKA.

In an aspect, the general area GENA may be formed to extend in the first direction DR1. The package area PCKA may extend in the first direction DR1 and then extend to protrude in the second direction DR2. Since the package area PCKA includes the package element PCD, the package area PCKA may include a bending portion, but the aspects of the present specification are not limited thereto. Depending on the sizes of the interlayer insulating film ILINSF, the package element PCD, and the circuit board CICB, the overlapping, protrusion relationship, or shape thereof may be modified.

The package area PCKA may have a first length L1 in the second direction DR2, and the general area GENA may have a second length L2 in the second direction DR2. The second length L2 may be the same as or different from the first length L1. The second length L2 may be smaller than the first length L1. Accordingly, the package area PCKA may be formed to have a shape that protrudes in the second direction DR2 or in a direction in which the circuit board CICB is disposed. The circuit board CICB may be attached to the protruding shape. In other words, the protruding shape of the interlayer insulating film ILINSF may be disposed between the circuit board CICB and the package element PCD in the third direction DR3 (or the thickness direction).

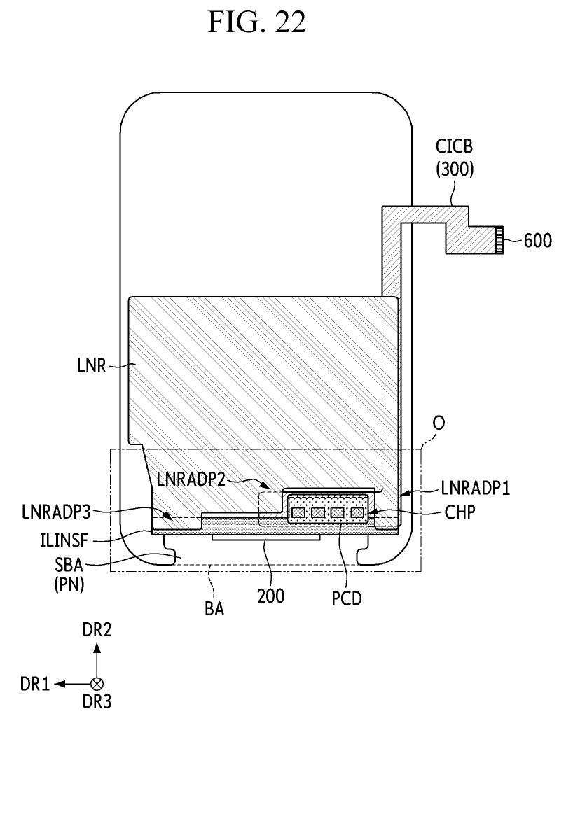

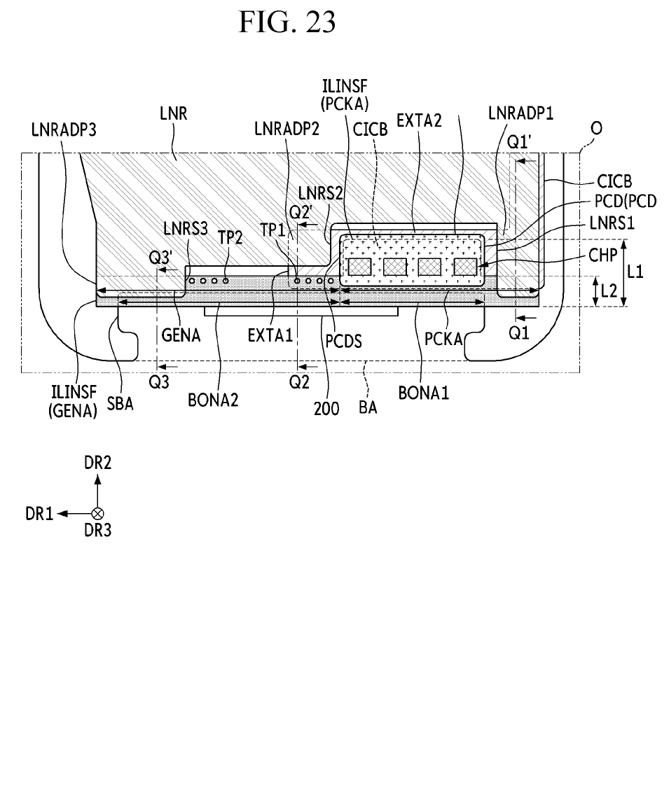

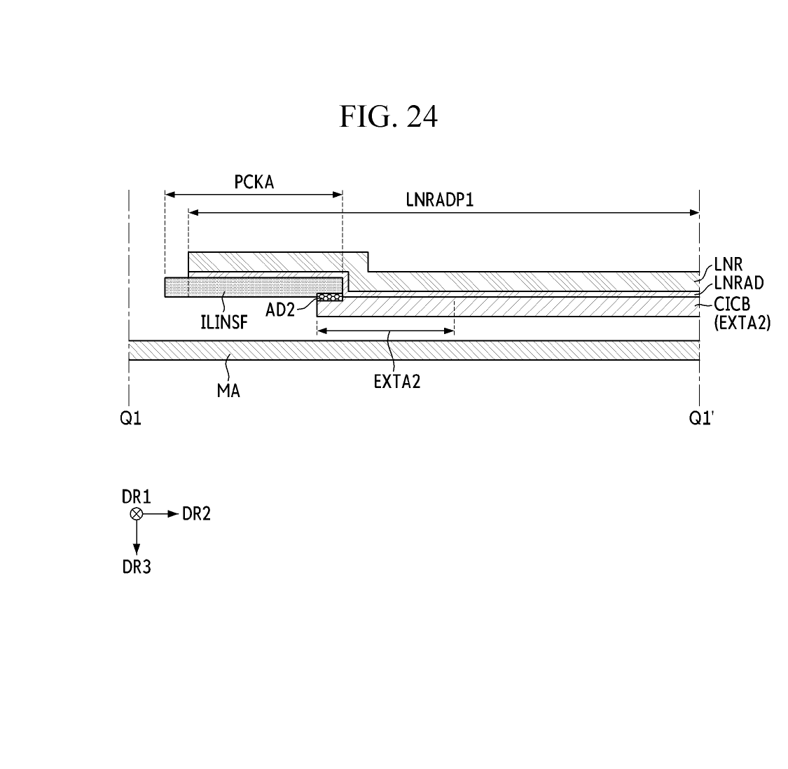

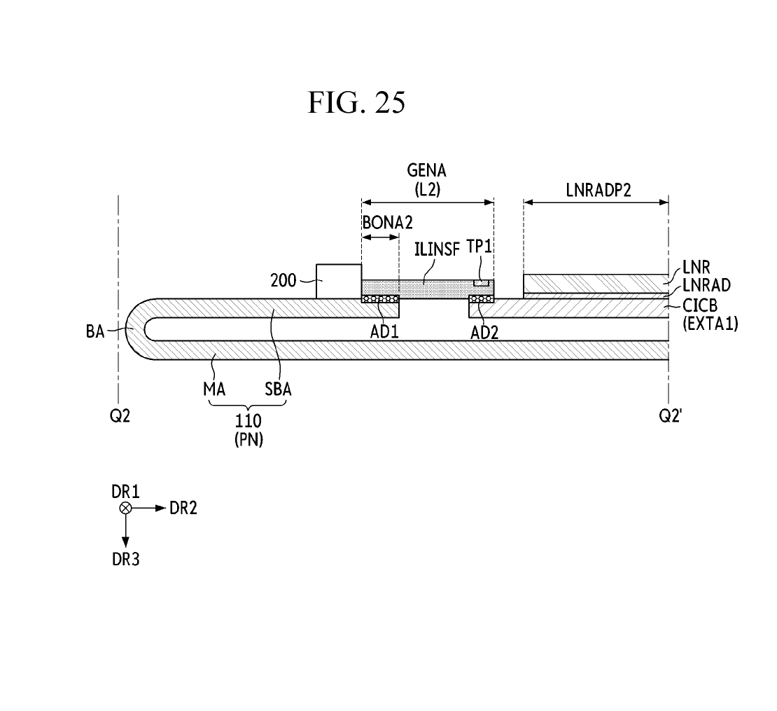

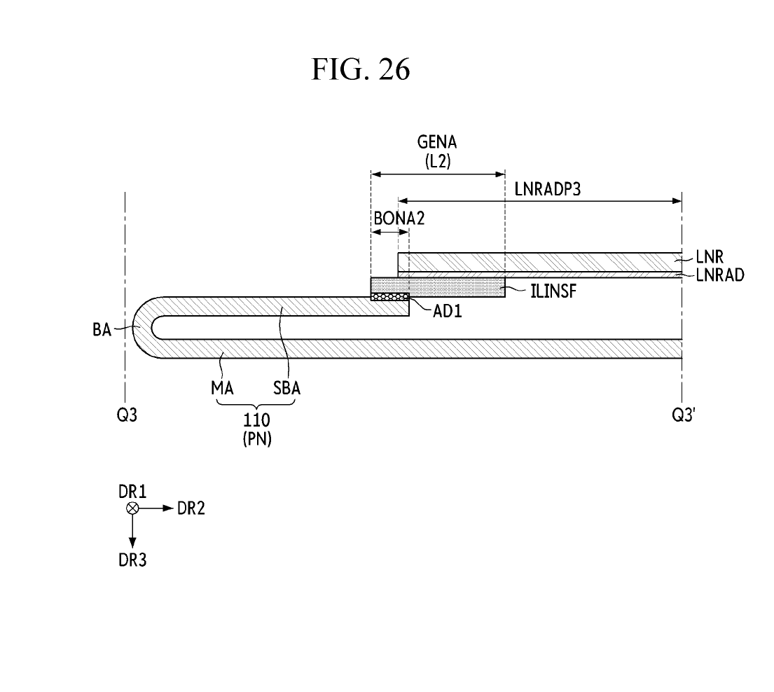

FIG. 22 is a plan view illustrating a state in which a display device according to a third aspect of the present specification is bent. FIG. 23 is a partial enlarged view illustrating area O of FIG. 22. FIG. 24 is a cross-sectional view illustrating a portion cut along the line Q1-Q1’ of FIG. 23. FIG. 25 is a cross-sectional view illustrating a portion cut along the line Q2-Q2’ of FIG. 23. FIG. 26 is a cross-sectional view illustrating a portion cut along the line Q3-Q3’ of FIG. 23.

Referring to FIGS. 22 and 23, the liner adhesive portion LNRADP may include a first liner adhesive portion LNRADP1, a second liner adhesive portion LNRADP2, and a third liner adhesive portion LNRADP3 that are spaced apart from each other. The second liner adhesive portion LNRADP2 may be disposed in the first direction DR1 from the first liner adhesive portion LNRADP1, and the third liner adhesive portion LNRADP3 may be disposed in the first direction DR1 from the second liner adhesive portion LNRADP2.

Referring to FIGS. 22, 23, and 24, the first liner adhesive portion LNRADP1 may overlap the second extension area EXTA2 of the circuit board CICB and the package area PCKA of the interlayer insulating film ILINSF in the third direction DR3 (or the thickness direction). The liner adhesive component LNRAD may be disposed between the circuit board CICB and the liner LNR in the third direction DR3 (or the thickness direction). The liner adhesive component LNRAD may be disposed between the interlayer insulating film ILINSF and the liner LNR in the third direction DR3 (or the thickness direction).

To this end, the interlayer insulating film ILINSF according to the third aspect may have a length in the first direction DR1 that is greater than that of the interlayer insulating film ILINSF according to the first or second aspect. The increased portion of the interlayer insulating film ILINSF may overlap the first liner adhesive portion LNRADP1 in the third direction DR3 (or the thickness direction). An adhesive portion of the circuit board CICB and the liner LNR extending in the second direction DR2 may be formed to be connected to the first liner adhesive portion LNRADP1.

Referring to FIGS. 22, 23, and 25, the second liner adhesive portion LNRADP2 may overlap the first extension area EXTA1 of the circuit board CICB in the third direction DR3 (or the thickness direction). The liner adhesive component LNRAD may be disposed between the circuit board CICB and the liner LNR in the third direction DR3 (or the thickness direction).

Referring to FIGS. 22, 23, and 26, the third liner adhesive portion LNRADP3 may overlap the general area GENA of the interlayer insulating film ILINSF in the third direction DR3 (or the thickness direction). The liner adhesive component LNRAD may be disposed between the interlayer insulating film ILINSF and the liner LNR in the third direction DR3 (or the thickness direction).

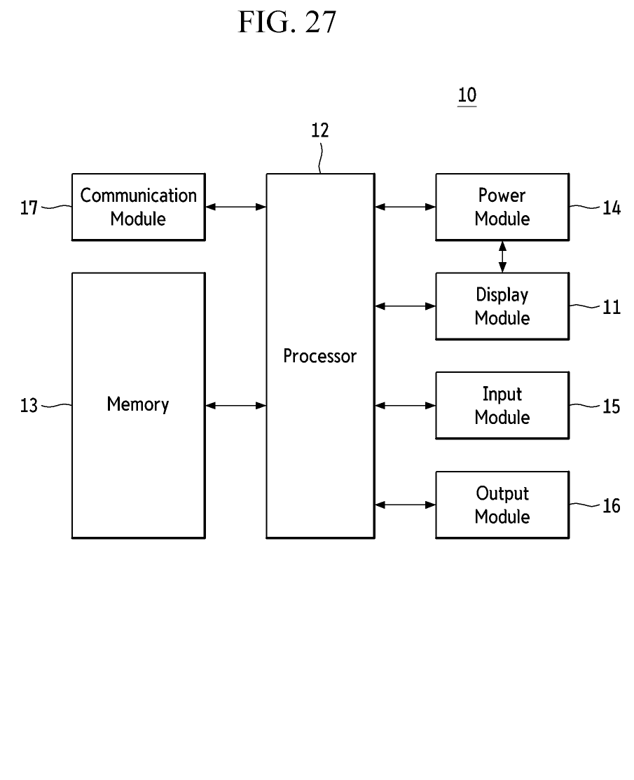

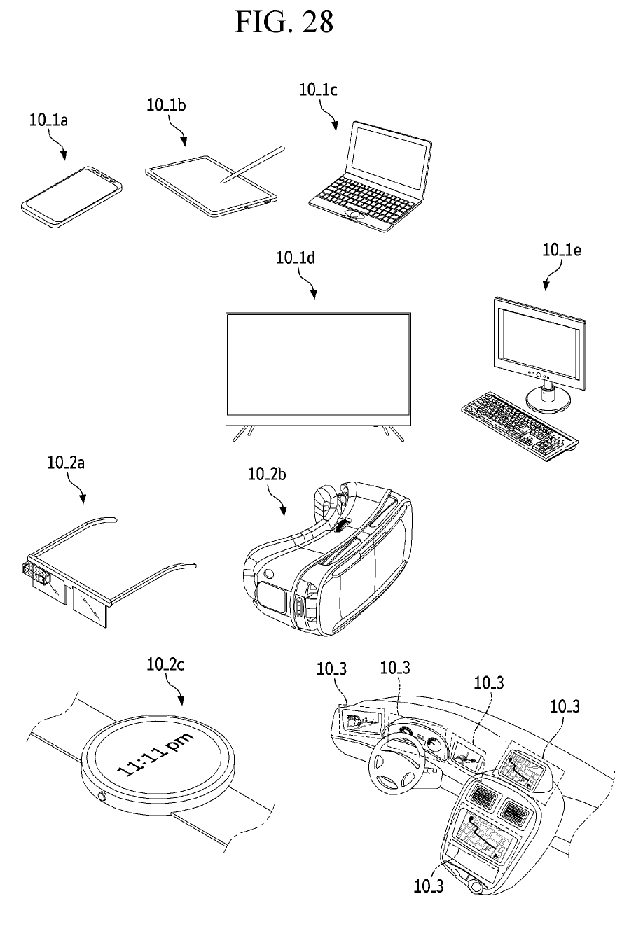

FIG. 27 is a block diagram of an electronic display device according to an aspect of the present specification. FIG. 28 illustrates schematic diagrams of electronic devices according to various aspects of the present specification.

Referring to FIG. 27, an electronic device 10 according to an aspect may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module such as a power adapter or a battery device. The power module 14 may include a power conversion module. The power conversion module may convert the power supplied by the power supply module to generate power required for the operation of the electronic device 10.

At least one of the components of the electronic device 10 described above may be included in the display device according to the above-described aspects. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device other than the display device.

The electronic device 10 may further include an input module 15, a non-image output module 16, and/or a communication module 17.

The input module 15 may provide input information to the processor 12 and/or the display module 11. The input module 15 may include various sensor modules as well as physical buttons, a keyboard, and a microphone. Examples of the sensor module may include a touch sensor, a pressure sensor, a distance sensor, a position sensor, a digitizer, a motion recognition sensor, a camera sensor, a photodetector, a photoelectric conversion sensor, a temperature sensor, as well as biosensors such as a blood pressure sensor, a blood sugar sensor, an electrocardiogram sensor, and a heart rate sensor.

The non-image output module 16 may serve to receive information other than the image received from the processor 12 and provide the information to the user. Examples of the non-image output module 16 may include an audio module, a haptic module, a light emitting module, etc., and may include other functional modules unique to the electronic device (e.g., a cooling module of a refrigerator, etc.).

The communication module 17 is a module responsible for transmitting and receiving information between the electronic device 10 and an external device, and may include a receiving unit and a transmitting unit. The communication module 17 may include various wireless communication modules such as a mobile communication module, a Wi-Fi module, and a Bluetooth module, or various wired communication modules.

Referring to FIG. 28, various electronic devices to which the display device according to the aspects of the present disclosure is applied may include electronic devices for displaying images, such as a smartphone 10_1a, a tablet PC 10_1b, a laptop 10_1c, a TV 10_1d, or a desk monitor 10_1e. In addition, various electronic devices to which the display device according to the aspects of the present disclosure is applied may include a wearable electronic device including a display module such as a smart glasses 10_2a, a head mounted display 10_2b, a smart watch 10_2c, or the like, and a vehicle electronic device 10_3 including a display module such as a Center Information Display (CID), a room mirror display, etc., disposed on a vehicle’s instrument panel, center fascia, or dashboard.

Although aspects of the disclosure have been described above with reference to the accompanying drawings, it will be understood by those having ordinary skill in the technical field to which the disclosure belongs that the disclosure may be practiced in other specific forms without altering the technical idea or features of the disclosure. It should therefore be understood that the aspects described above are exemplary in all respects and are not intended to be limiting.

What is claimed is:

1. A display device comprising:
a display panel including a main area extending in a first direction and a second direction intersecting the first direction, and a sub-area protruding in the second direction from a first side of the main area;
an interlayer insulating film attached to the sub-area of the display panel;
a package element at least partially disposed on the interlayer insulating film;
a circuit board attached to the interlayer insulating film; and
a liner, wherein at least a portion of the liner is disposed on at least a portion of the interlayer insulating film,
wherein the interlayer insulating film includes a package area and a general area, wherein the general area is in the first direction from the package area,
the package element is in the package area,
the package element includes a side surface extending in the second direction,
the liner includes a liner adhesive portion adhered to the interlayer insulating film or the circuit board,
the liner adhesive portion includes a side surface extending in the second direction, and
the side surface of the liner adhesive portion overlaps at least a portion of the side surface of the package element in the first direction.

2. The display device of claim 1, wherein the package area of the interlayer insulating film has a first length in the second direction,
the general area of the interlayer insulating film has a second length in the second direction, and
the first length is the same as the second length.

3. The display device of claim 1, wherein the liner adhesive portion overlaps the general area of the interlayer insulating film in a thickness direction of the display panel, wherein the thickness direction is normal to the first direction and the second direction.

4. The display device of claim 3, wherein the interlayer insulating film further includes a first test pad and a second test pad in the general area,

5. The display device of claim 4, wherein the liner adhesive portion is between the first test pad and the second test pad in the first direction.

6. The display device of claim 4, wherein the display device is in a bent form,
the first test pad is spaced apart from the main area of the display panel by a first height,
the second test pad is spaced apart from the main area of the display panel by a second height, and
the first height is the same as the second height.

7. The display device of claim 1, wherein the package area of the interlayer insulating film has a first length in the second direction,
the general area of the interlayer insulating film has a second length in the second direction, and
the first length is different from the second length.

8. The display device of claim 1, wherein the circuit board includes:
a first extension area, wherein the first extension area is elongated in the first direction and overlaps the general area of the interlayer insulating film in the second direction; and
a second extension area, wherein the second extension area is elongated in the first direction and overlaps the package area of the interlayer insulating film in the second direction, and
wherein the liner adhesive portion overlaps the first extension area in a thickness direction of the display panel, wherein the thickness direction is normal to the first direction and the second direction.

9. The display device of claim 8, wherein the circuit board further includes a first test pad and a second test pad in the first extension area,

10. The display device of claim 9, wherein the liner adhesive portion is between the first test pad and the second test pad in the first direction.

11. The display device of claim 9, wherein the display device is in a bent form,
the first test pad is spaced apart from the main area of the display panel by a first height,
the second test pad is spaced apart from the main area of the display panel by a second height, and
the first height is the same as the second height.

12. The display device of claim 1, wherein the liner adhesive portion includes a first liner adhesive portion overlapping the interlayer insulating film and the circuit board in a thickness direction of the display panel, wherein the thickness direction is normal to the first direction and the second direction.

13. The display device of claim 12, wherein the circuit board includes:
a first extension area, wherein the first extension area is elongated in the first direction and overlaps the general area of the interlayer insulating film in the second direction; and
a second extension area, wherein the second extension area is elongated in the first direction and overlaps the package area of the interlayer insulating film in the second direction, and
wherein the liner adhesive portion further includes a second liner adhesive portion, and the second linear adhesive portion overlaps the first extension area in the thickness direction of the display panel.

14. The display device of claim 13, wherein the liner adhesive portion further includes a third liner adhesive portion overlapping the general area of the interlayer insulating film in the thickness direction of the display panel.

15. An electronic device comprising:
a processor configured to provide an image signal;
a display module configured to receive the image signal from the processor and display an image; and
a power module configured to supply power to the display module,
wherein the display module includes:
a display panel including a main area extending in a first direction and a second direction intersecting the first direction, and a sub-area protruding in the second direction from a first side of the main area;
an interlayer insulating film attached to the sub-area of the display panel;
a package element at least partially disposed on the interlayer insulating film;
a circuit board attached to the interlayer insulating film; and
a liner, wherein at least a portion of the liner is disposed on at least a portion of the interlayer insulating film,
the interlayer insulating film includes a package area and a general area, wherein the general area is in the first direction from the package area,
the package element is in the package area,
the package element includes a side surface extending in the second direction,
the liner includes a liner adhesive portion adhered to the interlayer insulating film or the circuit board,
the liner adhesive portion includes a side surface extending in the second direction, and
the side surface of the liner adhesive portion overlaps at least a portion of the side surface of the package element in the first direction.

16. The electronic device of claim 15, wherein the package area of the interlayer insulating film has a first length in the second direction,
the general area of the interlayer insulating film has a second length in the second direction, and
the first length is the same as the second length.

17. The electronic device of claim 15, wherein the liner adhesive portion overlaps the general area of the interlayer insulating film in a thickness direction of the display panel, wherein the thickness direction is normal to the first direction and the second direction.

18. The electronic device of claim 15, wherein the package area of the interlayer insulating film has a first length in the second direction,
the general area of the interlayer insulating film has a second length in the second direction, and
the first length is different from the second length.

19. The electronic device of claim 15, wherein the circuit board includes:
a first extension area, wherein the first extension area is elongated in the first direction and overlaps the general area of the interlayer insulating film in the second direction; and
a second extension area, wherein the second extension area is elongated in the first direction and overlaps the package area of the interlayer insulating film in the second direction, and
wherein the liner adhesive portion overlaps the first extension area in a thickness direction of the display panel, wherein the thickness direction is normal to the first direction and the second direction.

20. The electronic device of claim 15, wherein the liner adhesive portion includes a first liner adhesive portion overlapping the interlayer insulating film and the circuit board in a thickness direction of the display panel, wherein the thickness direction is normal to the first direction and the second direction.
